(19) United States
(12) Patent Application Publication
(10) Pub. No.: US 2010/0044845 A1
(43) Pub. Date: Feb. 25, 2010

(54) CIRCUIT SUBSTRATE, AN ELECTRONIC DEVICE ARRANGEMENT AND A MANUFACTURING PROCESS FOR THE CIRCUIT SUBSTRATE

(75) Inventors: Takuo Funaya, Minato-ku (JP); Shintaro Yamamichi, Minato-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC Corporation, Minato-ku, Tokyo (JP)

(21) Appl. No.: 12/298,737

(22) PCT Filed: Apr. 27, 2007
(86) PCT No.: PCT/JP2007/059271

§ 371 Date: Nov. 2, 2009

(30) Foreign Application Priority Data
Apr. 27, 2006 (JP) 2006-150631

(51) Int. Cl. H01L 23/52; H01L 23/48; H01L 21/50; H01L 21/768

(52) U.S. Cl. 257/685; 257/698; 438/107; 438/121; 257/E23.141; 257/E23.01; 257/E21.499; 257/E21.575

(57) ABSTRACT

[Problem to be Solved] There are provided a circuit substrate, an electronic device arrangement and a manufacturing process for the circuit substrate which enable to directly implement the surface mounting and so on of electronic components on the conductive wiring without forming solder resist, and also which enable to enhance high speed transmission characteristics and to enlarge wiring rule for the electrode terminal of the function element to be contained therein, and to implement with excellent workability and reliability when connecting the electronic device.

[Solution] A circuit substrate comprising
a function element 1 with an electrode terminal 5
a base member containing the function element 1 therein and having at least one layer of a conductive wiring formed on its front side face and rear side face respectively, and
a via 6 connecting the electrode terminal 5 with the conductive wiring 3 formed on the base member, wherein the conductive wiring formed on either one of the front side face and the rear side face of the base member is arranged such that a surface exposed outside from the base member is in the same plane with or inside a surface of the base member on which the conductive wiring is formed.

### FIELD OF THE INVENTION

The present invention relates to a circuit substrate, an electronic device arrangement and a manufacturing process for the circuit substrate, specifically to the circuit substrate having a built-in function element, the electronic device arrangement provided with the circuit substrate and the manufacturing process for the circuit substrate.

### BACKGROUND OF THE INVENTION

Recently, density growth of wiring density has become a critical technical problem in the circuit substrate mounting the function element in accordance with offering technical advantages and miniaturization of the function element.

In Patent Literature 1, for example, a technique is disclosed in which, an insulating layer with a cavity is formed on a metallic plate to fit in a semiconductor element as a function element, the semiconductor element is mounted on the metallic plate with its active side having an electrode terminal towards up, so-called with face up style, and then at least one layer of build up wiring layers due to semi additive method is formed using photosensitive resin, thereby forming a package of IC (Integrated Circuit).

Further, in Patent Literature 2 another technique is disclosed in which, a semiconductor element with a projection electrode called the bump in the art and a pattern substrate with a projection portion corresponding to the projection electrode of the semiconductor element are laminated in the form of face to face, resin is run into a gap between the semiconductor element and the pattern substrate, and then a solder ball is formed in a dimple formed in the resin at upper portions of the projection electrode obtained through removing the pattern substrate after curing the resin, thereby forming a semiconductor package.

Also, for example, in Patent Literature 3 still another technique is disclosed in which, an electrode pad of BGA (Ball Grid Array) is on a metallic pattern plate in advance, a semiconductor element is formed with the flip chip connection on a build up conductive wiring, some under-fill resin is run into the element, the substrate connected with the semiconductor element is sealed with mold resin, and then the electrode pad of BGA is exposed by removing the metallic pattern plate, thereby forming a semiconductor package.

Also, for example, in Patent Literature 4 still another technique is disclosed in which, after a semiconductor element is connected to a circuit substrate through the flip chip connection and so on, a substrate connected with this semiconductor element and the circuit substrate provided with a cavity and a through-via filled with conductive paste and so on are laminated by turn, and then a solder ball is formed at the substrate of the undermost layer, thereby forming a laminated semiconductor package.

Also, for example, in Patent Literature 5 still another technique is disclosed in which, in the state that lower semiconductor elements and upper semiconductor elements are laminated in series on a package substrate the lower semiconductor elements and the package substrate are connected through wire bonding and sealed by resin, then a spacer chip is located between the lower semiconductor elements and the upper semiconductor elements, a plurality of via holes and connection wiring layers are provided in the spacer chip, and a wiring group of the lower semiconductor elements and a wiring group corresponding to the upper semiconductor elements are formed with the flip chip connection through these via holes and connection wiring layers.

Also, in Patent Literatures 6 to 10 still another technique is disclosed in which, a reentrant is formed on a core substrate, a semiconductor element is mounted in the reentrant with its active side having an electrode terminal towards up, so-called with face up style using bond, and then wiring layers is built up on the electrode terminal of the semiconductor element, thereby extracting a package wiring directly through the via holes.

Also, in Patent Literature 11 still another technique is disclosed in which, a through hole is formed on a core substrate, a semiconductor element is contained with its active side having an electrode terminal towards up, a heat sink is directly attached to the back side of the semiconductor element, and then wiring layers are built up on the electrode terminal of the semiconductor element, thereby extracting a package wiring directly through the via holes, and also, a technique is disclosed in which an IC chip is contained within a multilayered printed-wiring board.

[Patent Literature 1] Japanese patent laid open (unexamined) No. 11-233678 gazette
[Patent Literature 2] Japanese patent laid open (unexamined) No. 2002-359324 gazette
[Patent Literature 3] Japanese patent laid open (unexamined) No. 2003-229512 gazette
[Patent Literature 4] Japanese patent laid open (unexamined) No. 2002-064178 gazette
[Patent Literature 5] Japanese patent laid open (unexamined) No. 2005-217205 gazette
[Patent Literature 6] Japanese patent laid open (unexamined) No. 2001-332863 gazette
[Patent Literature 7] Japanese patent laid open (unexamined) No. 2001-339165 gazette
[Patent Literature 8] Japanese patent laid open (unexamined) No. 2002-084074 gazette
[Patent Literature 9] Japanese patent laid open (unexamined) No. 2002-170840 gazette
[Patent Literature 10] Japanese patent laid open (unexamined) No. 2002-246504 gazette
[Patent Literature 11] Japanese patent laid open (unexamined) No. 2001-352174 gazette

### DISCLOSURE OF THE INVENTION

### Problem to be Solved by the Invention

In the prior arts mentioned above, however, there are some problems as followings.

In the technique disclosed in the Patent Literature 1, photosensitive resin is unable to contain silica filler or glass cloth and so on when the photosensitive resin is used for forming wiring layers, because of loosing resolution. Due to such a reason there are problems that reliability on strength of resin layers is not enough, and reliability as a package is not enough. Further, because the build up wiring is formed only on the side with which the electrode terminal of the semiconductor element is provided, there is a problem that such technique can not be used as the circuit substrate except the package. Still further, there is a problem that, in case of a semiconductor package unnecessary for heat dissipation the package with the metallic plate becomes large in weight more than necessary and its outwards form becomes thick.

In the technique disclosed in the Patent Literature 2, because the semiconductor element with the projection electrode and the pattern substrate with the projection portion corresponding to the projection electrode of the semiconductor element are laminated in the face to face form, the semiconductor package is formed in the same size with the semiconductor element.

Therefore, there is a problem that in case of a narrow pitch in the wiring rule, the wiring rule can not be expanded and accordingly it is impossible to apply to the surface mounting and so on.

Also, there is another problem that, due to misalignment caused when the pattern substrate and the projection electrode are laminated, the aperture area becomes small which may disturb wetting characteristic of the solder ball.

Further, there is another problem that, because the projection electrode is formed only on the side with which the electrode terminal of the semiconductor element is provided, such technique has no function for wiring and can not be used as the circuit substrate.

In the technique disclosed in the Patent Literature 3, because the wiring is formed only the side provided with the electrode terminal of the semiconductor element, there is a problem that such technique can not be used as the circuit substrate except the package.

Further, there is another problem that the heat dissipation effect can not be anticipated, because a metallic plate for heat dissipation can not be attached on the back side of the semiconductor element.

Further, there is still another problem that cost necessary for manufacturing circuit substrate and for mounting the semiconductor element does not change as usual and therefore, the cost down can not be anticipated, because the semiconductor element is connected in the form of ordinary flip chip connection after forming wiring layers of the circuit substrate.

In the technique disclosed in the Patent Literature 4, because the substrate with the cavity and the substrate connected to the semiconductor element are laminated by turn and formed through heat press to a package with integrated combination, there is a problem that organic resin layers with small rigidity remain in existence above and below the semiconductor element, and brittle semiconductor silicon or GaAs and so on may break or crack at the same time with pressing.

Further, because the wiring circuit formed in resin layers mounting the semiconductor element is formed by etching using a plate with the one side to be copper clad, there is a problem that wiring with pitches narrower than the semi additive method and so on can not be formed within the package.

Further, because the semiconductor element is connected in the form of ordinary flip chip connection,

There is another problem that cost necessary for manufacturing circuit substrate and for mounting the semiconductor element does not change as usual and therefore, the cost down can not be anticipated.

In the technique disclosed in the Patent Literature 5, because the wiring can not be expanded in case that the semiconductor element is the same size with the semiconductor package, and because the wiring rule can not be expanded in case that the wiring rule of the semiconductor device is a narrow pitch which limits area, there is a problem in the surface mounting that the mounting in the conventional mother board can not be mounted with the conventional mounting accuracy. Also, because the structure is with the wiring exposed only on the one side of the package, there is a problem in the technique that it can not be applied to other circuit substrates except the package. Further, since the wiring distance becomes very long in case of connecting with other electronic components because of connection through the mother board in the surface mounting form, there is a problem that the high speed electric property as a finished product is not good though the high speed electric property is good within the package.

In the techniques disclosed in the Patent Literature 6 to 10, because the core substrate locating immediately below the mounting position of the semiconductor element is formed with organic resin, and bending stress is exerted on the resin by adding pressure when the semiconductor element is mounted in the dimple of the core substrate, there is a problem that the semiconductor element thinner than 100 μm or so may crack.

Also, since there has a possibility to crack due to small rigidity of the resin and stress added at the drilling work in case that a via hole is formed in the core substrate using the drill and so on and further the semiconductor element is built-in on the periphery of the via hole, there is a problem that the via hole can not be formed in proximity to the built-in semiconductor element, thereby enlarging the outward size of the core substrate.

In the techniques disclosed in the Patent Literature 11, because the semiconductor element is mounted on the heat sink with the face up style and the conductive wiring layers are built up from the electrode terminal, there is a problem that no conductive wiring layer is on the heat sink side and accordingly it can not be used as the circuit substrate. Also, in the method in which an IC chip is contained within a multilayered printed-wiring board, it is necessary to connect to other electronic components through forming solder resist on the front face and the back face of the multilayered printed-wiring board. Therefore, there is a problem that high reliability for connection can not be achieved.

The present invention has been achieved by taking those problems into consideration.

Accordingly, the object of the present invention is to provide a circuit substrate, an electronic device arrangement and a manufacturing process for the circuit substrate which enable to directly implement surface mounting for electronic components on conductive wirings without forming solder resist, and to have high speed transmission characteristics, to expand wiring rule for electrode terminals of the built-in function element, and to mount with excellent workability and reliability in the process of connection to the electronic device.

### Means for Solving the Problem

The circuit substrate according to the present invention is characterized in that it is provided with a function element with an electrode terminal, base member which contains the function element therein and having at least one layer of conductive wirings formed on its front side and back side respectively, and a via connecting the electrode terminal with the conductive wiring formed in the base member wherein the conductive wiring formed at either one of the front side or back side of the base member is disposed such that a surface exposed outside from the base member is in the same plane with a surface of the substrate on which the conductive wiring is formed or inside.

By means of that, it is possible to integrate the function element with short distances inside the circuit substrate in the form of three dimensions, thereby enabling to form an excellent product with high speed transmission characteristics.

Since the outward shape of the circuit substrate containing the function element therein is larger than that of the function element to be contained, it is possible to expand the wiring rule for the electrode terminal of the function element at the front and the rear of the circuit substrate and to implement with excellent workability and reliability when the circuit substrate and a electronic device are connected in the following process. Also, since the conductive wiring formed at either one of the front side or the rear side of the base member is arranged such that the surface of the conductive wiring exposed outside from the base member is in the same plane with or inside the surface of the base member on which the conductive wiring is formed, it is possible to directly implement the surface mounting for electronic components on the surface of conductive wirings without forming solder resist, and to implement semiconductor flip chip connection.

The other circuit substrate according to the present invention is characterized in that it is provided with a function element with an electrode terminal which extends in the direction perpendicular to a surface, base member which contains the function element therein and having at least one layer of conductive wirings formed on its front side and rear side respectively, and a via connecting the electrode terminal with the conductive wiring formed on the front side of the base member, wherein the conductive wiring formed at the rear side of the base member is disposed such that a surface exposed outside from the substrate is in the same plane with or inside a surface of the base member on which the conductive wiring is formed.

It is preferable that the base member is provided with at least one resin layer.

The base member is provided with at least three resin layers, and it is preferable that the insulating layer contacting the side face of the function element in the base member has a coefficient of thermal expansion smaller than those of other insulating layers.

Also, it is preferable that the coefficient of thermal expansion of the resin layers contacting the side face of the function element is within +30% to the coefficient of thermal expansion of the function element.

The base member can be provided with a plurality of conductive wiring layers at its front and rear sides, and at least one via which connects between the conductive wirings of different conductive wiring layers.

The base member can be provided with at least one via which connects between the conductive wirings mounted on the surface and the rear surface of the base member.

It is preferable that the via connecting between the conductive wirings mounted on the surface and the rear surface of the base member is formed at both side faces interleaving the function element.

The conductive wirings can be provided in the rear surface of the function element, which is disposed inside the surface of the resin layer disposed at the most outward surface in either one of the front and rear surfaces of the base member.

It is preferable that there are two or more than two sorts of combinations between the conductive wirings in which at least one via is formed, which connects between the conductive wirings lying at upside and downside of the function element.

Two or more than two of the conductive wiring layers are formed on the side of the front surface, and the electrode terminal of the function element can be connected through at least one via with the conductive wiring mounted in the conductive wiring layers other than the conductive wiring layer formed immediately above the electrode terminal.

It is preferable that three or more than three of the conductive wiring layers are formed which are located above and below the function element, and the conductive wiring mounted in each conductive wiring layer can be connected through at least one via with the conductive wiring mounted in the conductive wiring layers other than the conductive wiring layer lying immediately above or below.

It is preferable that all the expanding directions of the inner diameter of the via through the thickness direction of the base member is oriented to the same direction.

In addition, at least one conductive wiring layer can be provided in the front and rear surfaces of the core substrate which defines the circuit substrate mentioned above.

The circuit substrate according to the present invention can contain at least one sort of the function element by the number of two or more than two.

Also, the circuit substrate according to the present invention can contain at least two function elements between which are electrically connected through the conductive wirings.

Also, the circuit substrate according to the present invention may have an arrangement in which all of the function elements are arranged in the horizontal direction to the through thickness direction of the substrate.

Further, the electrode terminals of all function elements can be arranged to orient in the same direction to the thickness direction of the base member.

Some or all of the function elements are electronic components which can be connected to conductive wirings by means of solder made of material which includes at least one kind of element selected from the group consisting of Sn, Ag, Cu, Bi, Zn and Pb.

It is preferable in the circuit substrate according to the present invention that a plurality of the above mentioned circuit substrates are arranged through thickness direction of the base member, and at least one pair of function elements in the circuit substrates disposed at the upper portion and the lower portion are electrically connected through conductive wirings.

It is preferable that at least one pair of function elements in the circuit substrate disposed at the upper portion and the lower portion are arranged such that the electrode terminals are disposed in the form of face to face.

In addition, a via made of conductive paste or solder paste can be provided between at least one pair of function elements in the circuit substrate disposed at the upper portion and the lower portion.

It is preferable that the circuit substrate is connected through a via and an adhesion layer to a multilayered wiring substrate formed with a plurality of insulating layers, a via and conductive wirings.

The via is made of conductive paste or unleaded solder paste made of material which includes at least one kind of element selected from the group consisting of Sn, Ag, Cu, Bi, Zn and Pb.

It is possible to provide with solder resist with an aperture at the front and rear surfaces of the circuit substrate.

The circuit substrate according to the present invention can still contain the circuit substrate mentioned above.

The electronic device arrangement according to the present invention has a feature of providing such a circuit substrate.

A manufacturing process for a circuit substrate according to the present invention is characterized in that it includes a process for forming at least one layer of a conductive wiring on a support plate, a process for mounting a function element on the conductive wiring, a process for containing the function element by sealing an outer circumference of the function element with a resin layer, a process for forming a via at a electrode terminal portion of the function element, a process for forming at least one of wiring layer on the function element and a process for removing the support plate.

Thus, through forming the conductive wiring layer on the support plate and mounting the function element thereon, the possibility is reduced that the function element is deformed or broken with a force caused by press even when the function element is brittle. Also, in the following process, even when an insulating resin layer is supplied to the outer circumference of the function element by pressing or laminating it is possible to manufacture a product with reliability without damaging the function element because of the support plate for the base.

Still further, the conductive wiring layer can be built up above the electrode terminal portion of the function element with the support plate attached on.

Therefore, even when the total film thickness of the insulating resin layer is thin, the breakage possibility of the function element due to bending and so on of the circuit substrate is reduced and further good workability can be held, in the processes of machining the via hole, plating and supplying the insulating resin layer.

Also, it is possible to form the via hole directly to the conductive wiring formed on the support plate. In this case, when the support plate is metallic it is possible to implement plating processing inside the via hole with large values in aspect ratio, thereby enhancing electrical reliability.

Also, finally, since the support plate is removed and then the conductive wiring of the rear surface of the circuit substrate is exposed, the portion in which the support plate existed becomes to have a shape such that the level of the conductive wiring surface is the same or in a dimple than that of the insulating resin surface. Accordingly, the surface of the insulating resin layer acts as solder resist even without supplying the solder resist, and also high reliability in connection can be got when semiconductor element and so on are mounted because the level of conductive wiring formed on the support plate is uniform.

Further also, since connection to the circuit substrate of the function element and formation of the circuit substrate are simultaneously implemented, it is possible to reduce the cost necessary for forming a whole package, which corresponds to the conventional total amount of the cost necessary for forming the circuit substrate and the cost necessary for mounting the function element.

Also, another manufacturing process for a circuit substrate according to the present invention is characterized in that it includes a process for forming at least one layer of a conductive wiring on a support plate, a process for forming at least one layer of resin on the conductive wiring, a process for mounting a function element on the resin layer, a process for containing the function element by sealing an outer circumference of the function element with a resin layer, a process for forming a via at a electrode terminal portion of the function element, a process for forming at least one of wiring layer on the function element and a process for removing the support plate.

In the case, two or more than two kinds of the function elements can be mounted.

Further, some or all of the function elements are electronic components, and the manufacturing process further includes a process for mounting by means of connecting the electronic components with solder made of material which includes at least one kind of element selected from the group consisting of Sn, Ag, Cu, Bi, Zn and Pb.

The manufacturing process may include a process for forming a via hole in the insulating resin from the opposite side to the support plate, and a process for implementing metallic plating inside the via hole.

In case of defining the circuit substrate formed by the manufacturing process of the circuit substrate mentioned above as a core substrate, the manufacturing process may further include a process for building up a conductive wiring layer on the front and rear surfaces of the core substrate.

The manufacturing process may include a process for connecting two of circuit substrates formed by the manufacturing process of the circuit substrate mentioned above, interleaving an adhesion layer with the via made of conductive paste or solder paste between the two circuit substrates, wherein the two circuit substrates are disposed up and down with face to face.

The manufacturing process may include a process for forming at least one of wiring layers on the support plate and a process for connecting two of circuit substrates formed by the manufacturing process of the circuit substrate mentioned above, interleaving an adhesion layer with the via made of conductive paste or solder paste between the two circuit substrates, wherein the two circuit substrates are disposed up and down with face to face.

The manufacturing process may include a process for removing the support plate, wherein at least one of the two circuit substrates is the circuit substrate before removing the support plate.

It is preferable that a process is implemented at least one time, wherein the above mentioned circuit substrate and other circuit substrate are disposed up and down with face to face, and are connected interleaving an adhesion layer with the via made of conductive paste or unleaded solder paste between the two circuit substrates.

The manufacturing process may include a process for removing the support plate, wherein at least one of the two circuit substrates is the one before removing the support plate, namely the one substrate in which the support plate remains.

The conductive paste or unleaded solder paste can be made of material which includes at least one kind of element selected from the group consisting of Sn, Ag, Cu, Bi, Zn and Pb.

It is preferable that the support plate is made of material which includes at least one kind of element selected from the group consisting of copper, iron, nickel, chromium, aluminum, titanium, silicon, nitrogen and oxygen.

Solder resist with an aperture can be formed on at least one side of the front and rear surfaces of the circuit substrate formed by the manufacturing process mentioned above.

In the present invention, semiconductor elements wired and formed in Si, GaAs, LiTaO3, LiNbO3 and Quartz and so on and chip components consisting of active elements such as SAW (Surface Acoustic Wave) filter or thin film function elements and so on or passive elements such as capacitor, resister and inductance and so on, are wired and formed in the printed board or the flexible substrate, and are preferably used as the function element. However, the function element is not limited to those.

Also, in the method for forming the via hole according to the present invention opening by laser such as UV (Ultra-Violet)-YAG (Yttrium Aluminum Garnet) laser or CO2 laser and so on are preferably used. However, the method is not limited to those. Also, the via can be opened by means of exposing and developing photosensitive resin as the insulating resin layer.

Further, as to the conductive via, the conformal via which is formed by plating only at the side of the via in the via aperture the conductive metal such as gold, silver, copper or nickel and so on using the plating method, or the filled via which is formed by filling plating metal in the via aperture is preferable. However the conductive via is not limited to those.

In the present invention, the conductive wiring exposed outwardly can be preferably formed through forming on the surface thin films such as copper, nickel, gold, silver, or Sn—Ag solder and so on, using non electrolytic plating, electrolytic plating, printed processing and so on, even when, for example, the conductive wiring is formed with copper plating. However, the material for the surface of the conductive wiring is not limited to those.

Also, on the uppermost surface of the circuit substrate according to the present invention, it is possible to preferably form solder resist layers with the aperture only at the necessary portions such that areas of the conductive wiring to be exposed on the surface is limited, thereby preventing oxidization, and occurrence of the short circuit is prevented between the conductive wirings when the electronic components and so on are mounted using solder.

Further, it is possible to form conductive wirings having oxidization preventing effect and with the excellent wettability to solder by means of forming on the surface of the conductive wirings exposed from the aperture portions thin films of copper, nickel, gold, silver, or Sn—Ag solder and so on, using non electrolytic plating, electrolytic plating, printed processing and so on.

The support plate in the present invention can be preferably used, which materials are ceramics such as silicon, glass, alumina, glass ceramics, titanium nitride or aluminum nitride, metal such as copper, stainless, iron or nickel and so on, or thick organic resin such as polyimide and so on. However, the material is not limited to those.

### EFFECT OF THE INVENTION

According to the present invention, since the conductive wiring formed at either one of the front side or the rear side of the base member is disposed such that a surface exposed outside from the base member is in the same plane with a surface of the base member on which the conductive wiring is formed or inside, it is possible to directly implement surface mounting for electronic components on the surface of conductive wirings without forming solder resist, and to implement semiconductor flip chip connection. In the case, since the outward form of the circuit substrate containing the function element is larger than that of the function element to be contained, which allows to expand the wiring rule for the electrode terminal of the function element at the front and the rear of the circuit substrate, it is possible to implement with excellent workability and reliability when the circuit substrate and a electronic device are connected in the following process.

Thus, it is possible to integrate the function elements with short distances inside the circuit substrate in a three dimensional way, thereby enabling to form a circuit substrate and an electronic device arrangement having the substrate with high speed transmission characteristics.

### BRIEF DESCRIPTION OF THE DRAWINGS

FIG. 1 is a schematic sectional view illustrating a circuit substrate according to the first embodiment of the present invention.

FIG. 2 is a schematic sectional view illustrating a circuit substrate according to the second embodiment of the present invention.

FIG. 3 is a schematic sectional view illustrating a circuit substrate according to the third embodiment of the present invention.

FIGS. 4 (a) and (b) are schematic sectional views illustrating a circuit substrate according to the fourth embodiment of the present invention.

FIG. 5 (a) to (g) are schematic views illustrating in stages a manufacturing process of a circuit substrate according to the fourth embodiment of the present invention.

FIGS. 6 (a) and (b) are schematic sectional views illustrating a circuit substrate according to the fifth embodiment of the present invention.

FIGS. 7 (a) to (j) are schematic sectional views illustrating a circuit substrate according to the fifth embodiment of the present invention.

FIG. 8 is a schematic sectional view illustrating a circuit substrate according to the sixth embodiment of the present invention.

FIGS. 9 (a) and (b) are schematic views illustrating in stages a manufacturing process of a circuit substrate according to the sixth embodiment of the present invention.

FIG. 10 (a) to (b) are schematic views illustrating in stages a manufacturing process of a circuit substrate according to the sixth embodiment of the present invention.

FIG. 11 is a schematic sectional view illustrating a circuit substrate according to the seventh embodiment of the present invention.

FIG. 12 is a schematic sectional view illustrating a circuit substrate according to the eighth embodiment of the present invention.

FIG. 13 is a schematic sectional view illustrating a circuit substrate according to the ninth embodiment of the present invention.

FIG. 14 is a schematic sectional view illustrating a circuit substrate according to the tenth embodiment of the present invention.

FIG. 15 is a schematic sectional view illustrating a circuit substrate according to the eleventh embodiment of the present invention.

FIG. 16 is a schematic sectional view illustrating a circuit substrate according to the twelfth embodiment of the present invention.

FIGS. 17 (a) and (b) are schematic views illustrating in stages a manufacturing process of a circuit substrate according to the twelfth embodiment of the present invention.

FIG. 18 is a schematic sectional view illustrating a circuit substrate according to the thirteenth embodiment of the present invention.

FIG. 19 (a) to (e) are schematic views illustrating in stages a manufacturing process of a circuit substrate according to the thirteenth embodiment of the present invention.

FIG. 20 is a schematic sectional view illustrating a circuit substrate according to the fourteenth embodiment of the present invention.

FIG. 21 is a schematic sectional view illustrating a circuit substrate according to the fifteenth embodiment of the present invention.

FIGS. 22 (a) and (b) are schematic views illustrating in stages a manufacturing process of a circuit substrate according to the fifteenth embodiment of the present invention.

FIG. 23 is a schematic sectional view illustrating a circuit substrate according to the sixteenth embodiment of the present invention.

FIG. 24 is a schematic view illustrating the step 1 of a manufacturing process of a circuit substrate according to the sixteenth embodiment of the present invention.

FIG. 25 is a schematic view illustrating the step 3 of a manufacturing process of a circuit substrate according to the sixteenth embodiment of the present invention.

FIG. 26 is a schematic view illustrating the step 3 of a manufacturing process of a circuit substrate according to the sixteenth embodiment of the present invention.

FIG. 27 is a schematic view illustrating the step 1 of another manufacturing process of a circuit substrate according to the sixteenth embodiment of the present invention.

FIG. 28 is a schematic view illustrating the step 2 of another manufacturing process of a circuit substrate according to the sixteenth embodiment of the present invention.

FIG. 29 is a schematic view illustrating the step 3 of another manufacturing process of a circuit substrate according to the sixteenth embodiment of the present invention.

FIG. 30 is a schematic view illustrating the step 1 of still another manufacturing process of a circuit substrate according to the sixteenth embodiment of the present invention.

FIG. 31 is a schematic view illustrating the step 2 of still another manufacturing process of a circuit substrate according to the sixteenth embodiment of the present invention.

FIG. 32 is a schematic view illustrating the step 3 of still another manufacturing process of a circuit substrate according to the sixteenth embodiment of the present invention.

FIG. 33 is a schematic sectional view illustrating a circuit substrate according to the seventeenth embodiment of the present invention.

FIG. 34 is a schematic sectional view illustrating a circuit substrate according to the eighteenth embodiment of the present invention.

(a) and (b) of FIG. 35 are schematic views illustrating in stages a manufacturing process of the circuit substrate 322 according to the eighteenth embodiment of the present invention.

FIG. 36 is a schematic sectional view illustrating a circuit substrate according to the nineteenth embodiment of the present invention.

### DESCRIPTION OF NOTATION

1, 12, 31, 32: function element
2, 40: adhesion layer 3, 3a, 3b, 4, 4a, 4b, 25, 26, 102, 103: conductive wiring 5, 13: electrode terminal
6, 7, 7a, 7b, 7c, 7d, 14, 15a, 15b, 16, 23, 24, 45, 92, 93, 95, 96: conductive via
8, 9, 10, 11, 21, 22, 94: insulating resin layer
51: solder resist
52: aperture
66, 67, 15: via hole
91, 301, 302, 303, 321, 322: circuit substrate
101: support plate
305, 306: build up layer
308: multilayered wiring substrate

### BEST MODE OF CARRYING OUT THE INVENTION

Then, the embodiments of the present invention will be explained with reference to the accompanying drawings.

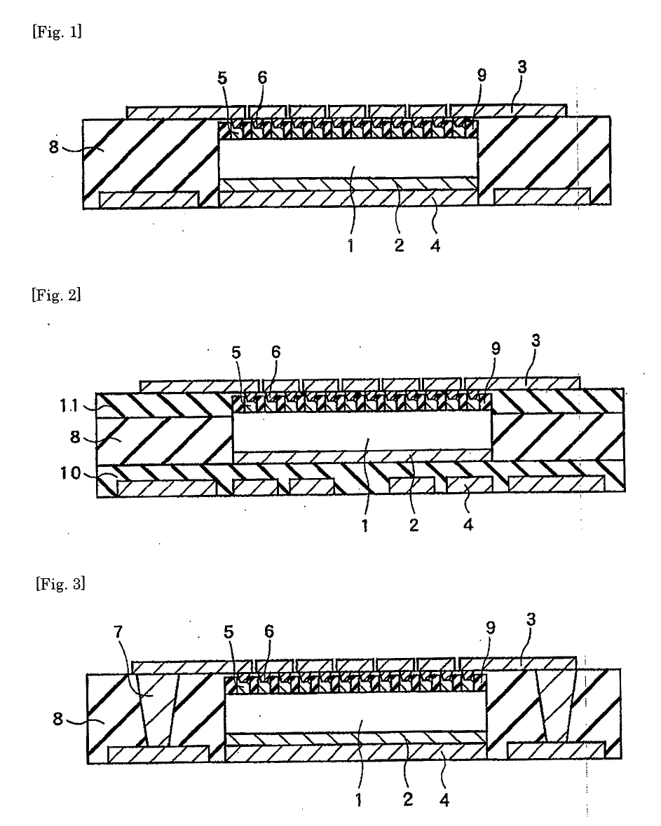

First, the first embodiment of the present invention will be explained.
FIG. 1 is a schematic sectional view illustrating a circuit substrate according to the first embodiment of the present invention. In the circuit substrate according to the first embodiment, a function element 1 having an electrode terminal 5 and an insulating resin layer 9 on its surface is sealed in an insulating resin layer 8 as a base member of the circuit substrate. A conductive wiring 3 formed on the surface of the insulating resin layer 8, and the electrode terminal 5 of the function element 1 is connected through a conductive via 6. Further, the rear face of the function element 1 and a conductive wiring 4 formed on the rear face of the insulating resin layer 8 with exposed are bonded inside the insulating resin layer 8 by an adhesion layer 2.
In FIG. 1, the surface exposing outside the conductive wiring 4 is disposed in the same plane with the rear face of the insulating resin layer 8. However, in the present embodiment, the surface exposing outside the conductive wiring 4 is not necessary to be disposed in the same plane with the rear face of the insulating resin layer 8. In other words, only contacting the side face of the conductive wiring 4 to the insulating resin layer 8 is necessary. Namely, the conductive wiring 4 may be immersed in the insulating resin layer 8 in the state that one face is exposed outside, thereby constituting the circuit substrate according to the present invention.

As to the function element 1, it can be used of the type which has the electrode terminal 5 made of copper on the surface, and which base member is GaAs or silicon. Further, the conductive wirings 3 and 4 can be formed by copper plating and so on with the thickness of 5 to 20 μm. Also, in other ways the conductive wirings 3 and 4 can be formed by the plating method or printed processing method and so on using at least one kind of copper, nickel, gold, silver or unleaded solder and so on. However, the forming method is not limited to those. Also, the conductive via 6 can be formed by means of the processing of copper plating inside the via hole, which connects the conductive wiring 3 formed on the surface of the insulating resin layer 8 with the electrode terminal 5 formed on the surface of the function element 1.

As the insulating resin layer 8 for the base member of the circuit substrate, the insulating resin 8 can be preferably used of the type which, for example, includes glass cloth within epoxy base member, aramid non woven fabric sheet or aramid film and so on, and which includes aramid non woven fabric sheet, aramid film, glass cloth and silica film and so on within resin base member such as epoxy, polyimide or liquid crystal polymer and so on, or polyimide and so on, for the purpose of reinforcement and enhancement of high speed transmission characteristics.

Also, because the function element 1 is built-in or contained inside the insulating resin layer 8 in the structure of the circuit substrate according to the present invention, it is possible to use the function element 1 without forming the insulating resin layer 9 on the function element 1 for the purpose of cost reduction.

The conductive wiring 4 formed on the rear face with exposed can be formed such that the surface exposed outside is in the same plane with the rear face of the insulating resin layer 8 or immersed by the thickness of 20 or less than 20 μm.

The rear face of the function element 1 can be connected to the conductive wiring 4 by semi hardened resin called “Die attachment film”, as the adhesion layer 2. Any of trade names [LE-4000], [LE-5000] manufactured by Lintec Co. and [DF402] manufactured by Hitachi Chemical Co. can be used as the “Die attachment film”.

In case that the rear face of the function element 1 and the conductive wiring 4 are joined with an adhesive by the adhesion layer 2 and the function element 1 is heated, it is possible to release the heat through the conductive wiring 4 outside the circuit substrate, thereby enabling to enhance the product reliability.

Further, when the portion in the conductive wiring 4, on which the function element 1 is mounted immediately above, is formed in the pattern in advance such that the portion has the same shape with the outward shape of the rear face, it is possible to get higher heat release effect. Simultaneously, since it plays the role of protecting the function element 1 from impact given from outside the circuit substrate, it is possible to further enhance the reliability for the circuit substrate. Particularly, in case that thickness of the function element 1 is 200 or less than 200 μm, it is preferable that the portion in the conductive wiring 4, on which the function element 1 is mounted immediately above, is formed in the pattern in advance such that the portion has the same shape with the outward shape of the rear face.

Also, since the conductive wiring 4 is formed in the pattern, and the insulating resin layer 8 in place is exposed outward, it is easy to reduce thermal stress produced by the difference of thermal expansion coefficients between the function element 1 and the conductive wiring 4 rather than that of the package in which metal with large area such as usual heat dissipation plate is pasted on the rear face of the function element 1. Thus, the circuit substrate according to the present embodiment is high in reliability and excellent in durability when used as the package.

Then, the performance of the circuit substrate according to the present embodiment, constituted as stated in the above will be explained.

The function element 1 generates heat when it operates. In the case, because the rear face of the function element 1 and the conductive wiring 4 are bonded with the adhesion layer 2, and in the conductive wiring 4 the side opposite to the face bonded with the function element 1 is exposed from the insulating resin layer 8, it is possible to effectively release the heat outside the circuit substrate. Further, in case that the conductive wiring 4 has the same shape with that of the rear face of the function element 1 mounted on immediately above, it is possible to obtain much higher release effect efficiently and simultaneously to play the role of protecting the function element 1 from impact given from outside the circuit substrate.

In the present embodiment since the conductive wiring 3 mounted on immediately above the function element 1 expands the wiring rule for the electrode terminal 5 in the surface of the function element 1, and the electronic components are directly mounted wherein the outer terminals of the electronic components are formed as the conductive wiring 3, it is possible to shorten the distance between those electronic components and the electrode terminal 5 of the function element 1, thereby enabling to obtain the electronic device arrangement with the excellent and high speed electrical property.

Further, in the rear face of the circuit substrate according to the present embodiment, since the conductive wiring 4 formed on the rear face with exposed can be formed such that the surface exposed outside is in the same plane with the rear face of the insulating resin layer 8 or immersed by the thickness of 20 or less than 20 μm, there is a small possibility to effect electric short between conductive wirings due to melting solder when the electronic component is mounted on the conductive wiring 4 directly by the solder. Therefore, it is not necessary to use solder resist, and then, the product with high reliability can be obtained.

Next, the second embodiment of the present invention will be explained. FIG. 2 is a schematic sectional view illustrating a circuit substrate according to the second embodiment of the present invention. In FIG. 2 the notation of the same constitutional element with that in FIG. 1 is identical, and then the detailed explanation of such element is omitted. In the present embodiment the explanation is about that the function element 1 mounted on the circuit substrate has low heat generation when operating.

The above stated circuit substrate for the first embodiment is provided with the function element 1 which is implemented in one kind of insulating resin layer 8. On the contrary, in the circuit substrate according to the present embodiment, the base member is constituted with at least three layers of the insulating resin layer 8, and the insulating resin layer contacting the side of the function element 1 is smaller than other insulating layers in the thermal expansion coefficient. Preferably, there is used insulating resin which thermal expansion coefficient is within +30% of the thermal expansion coefficient in the function element 1, thereby preventing a crack produced by the stress arising from the difference of the thermal expansion coefficient between the insulating resin layer 8 and the function element 1. FIG. 2 illustrates three layers of the insulating resin layer for constituting base member of the circuit substrate.

According to the circuit substrate of the present embodiment, inside an insulating resin layer 10 in which the conductive wiring 4 is formed with the rear face exposed, the rear face of the function element 1 is bonded to the conductive wiring 4, on the surface of which an electrode terminal 5 and an insulating resin layer 9 is provided. The side face of the function element 1 is sealed by the insulating resin layer 8, and the front surface of the function element 1 is sealed by an insulating resin layer 11 on the surface of which a conductive wiring 3 is formed.

As shown in FIG. 2, the face exposed outside the conductive wiring 4 is disposed in the identical plane with the rear face of the insulating resin layer 10. However, in the present embodiment it is not necessary that the face with exposed outside the conductive wiring 4 is disposed in the same plane with the rear face of the insulating resin layer 10, and only contacting the side face of the conductive wiring 4 to the insulating resin layer 10 is necessary. Namely, the conductive wiring 4 may be immersed in the insulating resin layer 10 in the state that one face is exposed outside, thereby constituting the circuit substrate according to the present embodiment.

For example, a function element can be used as the function element 1, which is provided with the electrode terminal 5 made of copper in the surface, and forms resister, capacitor, and/or inductance circuits by means of thin film deposition method using silicon, glass or polyimide as the base member.

Also, the conductive wiring 3 and 4 can be formed with copper. Further, the rear face of the function element 1 and the insulating resin layer 10 can be bonded through the adhesion layer 2 of epoxy base member.

The insulating resin layers 10, 8 and 11 can be respectively formed in the range of 10 to 500 μm in thickness. Those values of thickness are variable corresponding to the thickness of the function element 1 built-in there. Further, in the insulating resin layers 10 and 11 near the front and rear surfaces of the circuit substrate, polyimide system resin or epoxy system resin can be used which has flexibility for preventing the bending stress from outside and the crack. Also, since the electrode terminal 5 of the function element 1 is embedded in advance in the insulating resin layer 9, it is possible to select a sort of resin having better adhesiveness with the insulating resin layer 9, as the insulating resin layer 11. Further, since the electrode terminal 5 of the function element 1 is immersed inside the insulating resin layer 11, it is possible to use the insulating resin layer 9 without forming on the function element 1 for the purpose of cost reduction.

As the insulating resin 8 contacting the side of the function element 1, organic resin is used, including glass cloth, glass filler, aramid non woven sheet or aramid film and so on which thermal expansion coefficients are similar to the thermal expansion coefficient of the function element 1.

Accordingly, it is possible to prevent the crack arising from the bending stress produced by the difference of thermal expansion coefficients between the insulating resin later 8 and the function element 1. Thus, it is possible to enhance the reliability of the circuit substrate. In the present embodiment it is possible to stack the insulating resin layer to multi-layers in the manufacturing process without limiting to three of insulating resin layers. In the case, using high heat-resistant resin and low heat-resistant resin, and high cost resin and low cost resin by combinations of them it is possible to enhance the product reliability and at the same time to realize low cost.

Also, a conductive via 6 can be formed by copper plating or printing conductive paste inside the via hole, which connects the conductive wiring 3 formed on the surface of the insulating resin layer 11 with the electrode terminal 5 formed on the surface of the function element 1.

Then, the performance of the circuit substrate according to the present embodiment, constituted as stated in the above will be explained. In the circuit substrate according to the present embodiment, it is possible to interpose the resin layer 10 between the adhesion layer 2 and the conductive wiring 4, because the heat generation of the function element 1 is small when operating.

Thus, it is possible to form microscopic wiring patterns as the conductive wiring 3 and the conductive wiring 4 on the front surface of the insulating resin layer 11 disposed immediately above the function element 1 and on the rear surface of the insulating resin layer 10 disposed immediately below the function element 1. And, it is possible to implement surface mounting and semiconductor flip chip connection of electronic components to those of the conductive wiring 3 and the conductive wiring 4. Thus, since it is possible to make use of area of the circuit substrate effectively when mounting and to make the area of the circuit substrate to be small, the embodiment contributes to miniaturization of the electronic device arrangement.

Since the conductive wiring 3 mounted on immediately above the function element 1 expands the wiring rule for the electrode terminal 5 in the surface of the function element 1, and the electronic components are directly mounted wherein the outer terminals of the electronic components are formed as the conductive wiring 3, it is possible to shorten the distance between those electronic components and the electrode terminal 5 of the function element 1, thereby enabling to obtain the electronic device arrangement with the excellent and high speed electrical property.

Further, in the rear face of the circuit substrate according to the present embodiment, since the conductive wiring 4 formed on the rear face of the insulating resin layer 10 with exposed can be formed such that the surface exposed outside is in the same plane with the rear face of the insulating resin layer 10 or immersed, there is a small possibility to effect electric short between conductive wirings due to melting solder when the electronic component is mounted on the conductive wiring 4 directly by the solder. Therefore, it is not necessary to use solder resist, and then, the product with high reliability can be obtained.

Next, the third embodiment of the present invention will be explained. FIG. 3 is a schematic sectional view illustrating a circuit substrate according to the third embodiment of the present invention. In FIG. 3 the notation of the same constitutional element with that in FIGS. 1 and 2 is identical, and then the detailed explanation of the element is omitted. In the second embodiment stated above, the conductive wiring 3 formed on the surface of the insulating resin layer 8 as the base member and connected through the via 6 to the electrode terminal 5 of the function element 1, and the conductive wiring 4 formed so as to expose its surface from the rear face of the insulating resin layer 8 are insulated by the insulating resin layer 8. On the contrary, in the present embodiment a part of the conductive wiring 3 and a part of the conductive wiring 4 are connected through a via hole 7 formed by filling metal or conductive paste inside a via hole formed in the insulating resin layer 8. The difference between the second and the third embodiments lies only in that point stated above, and the rest has the same structure with the second embodiment.

A function element can be used as the function element 1, which is provided with the electrode terminal 5 made of copper in the surface, and provided with GaAs as the base member.

The rear face of the function element 1 and the conductive wiring 4 can be bonded by the adhesion layer 2 made of Ag paste which is obtained by kneading Ag powder in epoxy system resin.

Thus, in case that the function element 1 generates heat, it is possible to release the heat through the conductive wiring 4 made of copper outside the circuit substrate, thereby enabling to enhance the product reliability.

It is possible to form the conductive wiring 3 and the conductive wiring 4, and the conductive via 6 and the conductive via 7 by means of copper plating processing. In addition to this it seems to be preferable to use one or more than one kind of nickel, gold, silver or unleaded solder and so on as the materials for the conductive wiring 3 and the conductive wiring 4, and the conductive via 6 and the conductive via 7. However the material is not limited to those. It is possible to form the via holes for forming the conductive via 6 and the conductive via 7 by laser processing from above the insulating resin layer 8. By this the inner diameter of the via hole for forming the conductive via 6 and 7 becomes all small in the rear side surface of the circuit substrate, and becomes all large in the front side surface of the circuit substrate. By this, for example, because of heating by the laser beam, there may cause to happen about ten portions expanded towards inner side of the via hole at a part of the insulating resin layer 8 in the vicinity of the bottom of the via hole. However, because the taper of the via hole is directed to the same direction, in the process of metallic plating inside the via hole it is easy to observe the plating portions, to judge the state of well plating and faulty portions, and to implement metallic plating again when faulty portions are observed, thereby enabling to enhance the product quality. Also, as for the conductive via 7, in case that the ratio of the inner diameter at upper portion of a via hole to the height of the via hole is larger than 1 it is possible to form the conductive via 7 by filling unleaded solder paste or conductive paste and so on into such a via hole using the printed method.

Such material as epoxy, polyimide or liquid crystal polymer can be preferably used as the base member for the insulating resin 8. However the material is not limited to those. Further, aramide non woven sheet, aramide film, glass cloth or silica film can be preferably used within the insulating resin 8 as the inclusion material. However, the inclusion material is not limited to those.

Then, the performance of the circuit substrate according to the present embodiment, constituted as stated in the above will be explained.

In addition to the operation according to the first embodiment, the circuit substrate according to the present embodiment has the following operation and effect. Namely, because the conductive via 7 implements by the shortest way the connection between the conductive wiring 3 and the conductive wiring 4 in the front and rear faces of the circuit substrate, it is possible to enhance the electric characteristics to the high speed level of more than 1 G Hz between electronic components, and between the function element 1 and those components built in the front and rear faces of the circuit substrate, thereby enabling to obtain the electronic device arrangement with the excellent and high speed electric characteristics.

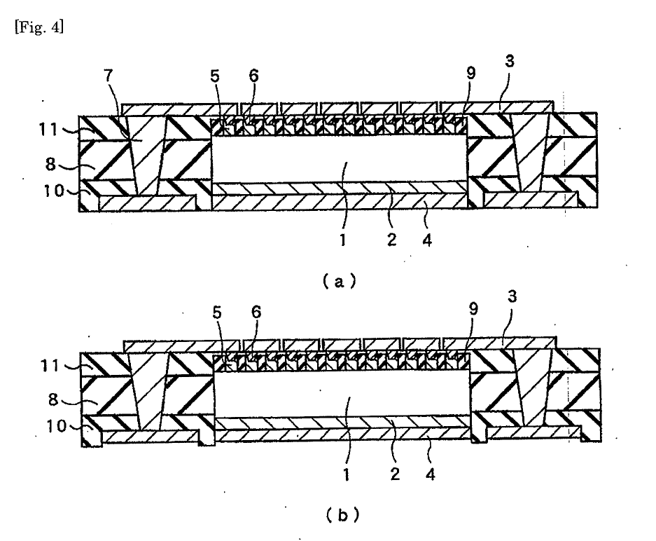

Next, the fourth embodiment of the present invention will be explained. FIGS. 4 (a) and (b) are schematic sectional views illustrating a circuit substrate according to the fourth embodiment of the present invention.

In FIG. 4 the notation of the same constitutional element with that in FIGS. 1 to 3 is identical, and then the detailed explanation of the element is omitted.

In the circuit substrate according to the second embodiment stated above, the conductive wiring 3 formed on the surface of the insulating resin layer 11 and connected through the via 6 to the electrode terminal 5 of the function element 1, and the conductive wiring 4 formed so as to expose its surface from the rear face of the insulating resin layer 10 are insulated by the insulating resin layers 10, 8 and 11. On the contrary, in the circuit substrate according to the present embodiment a part of the conductive wiring 3 and a part of the conductive wiring 4 are connected through a via hole 7 formed by filling metal or conductive paste inside a via hole formed in the insulating resin layers 10, 8 and 11. The difference between the second and the present embodiments lies only in that point stated above, and the rest has the same structure with the second embodiment.

As shown in FIG. 4(a), it is not necessary that the face with exposed outside the conductive wiring 4 is disposed in the same plane with the rear face of the insulating resin layer 10, and only contacting the side face of the conductive wiring 4 to the insulating resin layer 10 is necessary. Namely, as shown in FIG. 4(b), the conductive wiring 4 may be immersed in the insulating resin layer 10 in the state that one face is exposed outside.

The insulating resin layer for constituting base member of the circuit substrate is not limited to three layers, but is constituted with at least three layers of the insulating resin layer. And as the insulating resin layer 8 contacting the side of the function element 1, there is used such an insulating resin smaller than other insulating resin layers in the thermal expansion coefficient. And preferably, there is used the insulating resin which thermal expansion coefficient is within +30% of the thermal expansion coefficient in the function element 1, thereby preventing a crack produced by the stress arising from the difference of the thermal expansion coefficients between the insulating resin layer 8 and the function element 1.

FIG. 4 illustrates three layers of the insulating resin layer for constituting base member of the circuit substrate.

Then, the performance of the circuit substrate according to the present embodiment, constituted as stated in the above will be explained.

In addition to the operation according to the second embodiment, the circuit substrate according to the present embodiment has the following operation and effect. By means of directly implementing the electronic components in the conducting wiring 3 disposed immediately above the function element 1, it is possible to shorten the distance between those electronic components and the electrode terminal 5 of the function element 1, thereby enabling to obtain the electronic device arrangement with the excellent and high speed electric property. In the case, because the conductive via 7 implements by the shortest way the connection between the conductive wiring 3 and the conductive wiring 4 in the front and rear faces of the circuit substrate, it is possible to enhance the electric characteristics to the high speed level of more than 1 G Hz between electronic components, and between the function element 1 and those components built in the front and rear faces of the circuit substrate, thereby enabling to obtain the electronic device arrangement with the excellent and high speed electric characteristics.

Next, a manufacturing process of the circuit substrate according to the present embodiment will be explained.

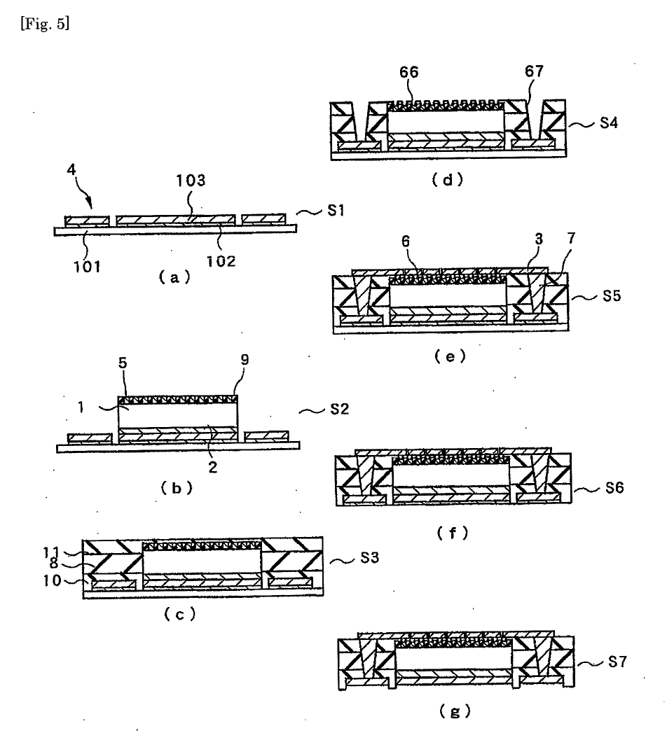

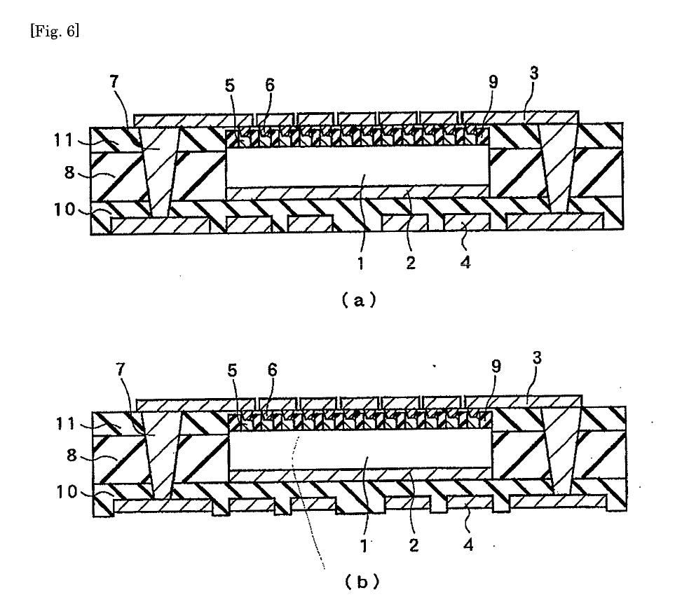

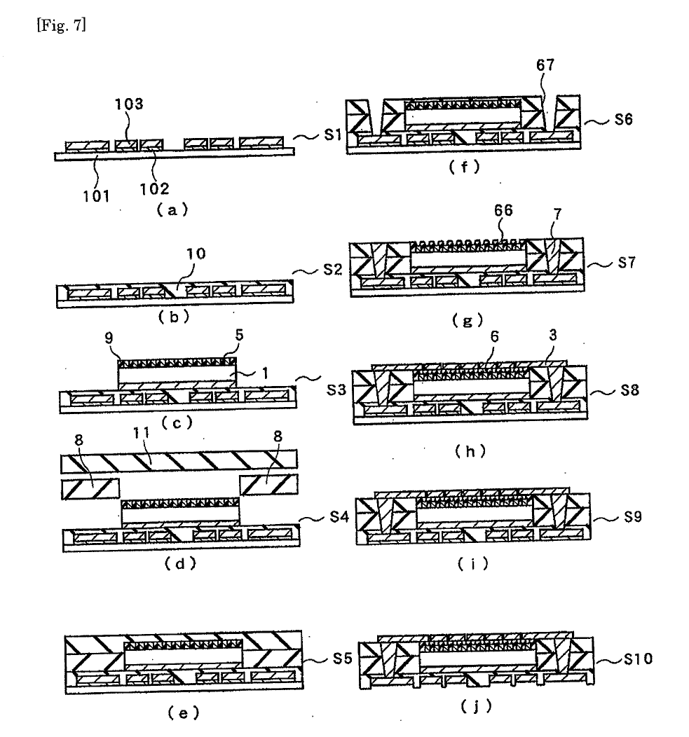

FIG. 5 (a) to (g) are schematic views illustrating in stages the manufacturing process of the circuit substrate according to the fourth embodiment of the present invention. In FIG. 5 the notation of the same constitutional element with that in FIGS. 1 to 4 is identical, and then the detailed explanation of the element is omitted.

First, resist for plating is supplied on a metallic support plate 101. After exposure and development, a conductive wiring 102 is formed by the plating method. Then, this resist for plating is used as is, or the resist for plating is once peeled and then the resist is supplied again on the support plate 101. After patterning by exposure and development, a conductive wiring 103 is formed by the plating method to the given thickness and then the resist for plating is peeled. (Step 1). Thus, the conductive wiring 4 is formed with two metallic layers. For example, it is possible to use the resist for plating made of dry film or varnish.

The support 101 is finally removed. For example, in case that the support plate 101 is removed by etching it is preferable that the conductive wiring 102 does not dissolve in the etching solution during etching. Therefore, it is preferable that the conductive wiring 102 is different in material from the support plate 101. Also, because the conductive wiring 102 is provided with a metallic surface with the surface exposed after the support plate 101 is removed, gold or solder is preferably used. However, the preferable material is not limited to those. Further, the conductive wiring 102 is not limited to one plating layer. The conductive wiring 102 can be formed by a plurality of plating layers.

Also, because the conductive wiring 102 still remains as the conductive wiring after the support plate 101 is removed, it is preferable that the conductive wiring is formed by gold, copper or nickel and so on. However, the formation of the conductive wiring is not limited to those. Also, when a blanket metallic area is pattern-formed in advance at the portion on which the function element 1 is mounted immediately above in the conductive wiring 102 and the conductive wiring 103, which has the same shape with the outward shape of the rear face of the function element 1, it is preferable to do such a pattern formation because this blanket metallic area acts as a heat release plate after the support plate 101 is removed. However, the heat release means is not limited to this.

In addition, in case that the support plate 101 is removed by mechanically polishing or peeled by stress and so on, not by etching the support plate 101, it is not necessary to form the conductive wiring 102. Namely, in such case, it is possible to directly form the conductive wiring 103 on the support plate 101.

In the next, an adhesion layer 2 is disposed on the conductive wiring 103, and then the function element 1 having the electrode terminal 5 on the surface is through the adhesion layer 2 mounted on the conductive wiring 103 by heating and pressing. (Step 2). The electrode terminal 5 in the surface of the function element 1 can be formed with a cylindrical shape or made of multi-wiring. However, the shape of electrode terminal 5 is not to those. Further, it is possible to implement insulating resin 9 in the surface of the function element 1 in case that it is necessary to protect the active surface of the function element 1. Further, in the case, the electrode terminal 5 can be implemented so as not to expose on the surface with immersed in the insulating resin 9.

For example, it is possible to use organic resin with the thickness of 10 to 30 μm as the adhesion layer 2. In the case it is possible to use the function element 1 with the thickness of 10 to 725 μm.

In the next, at least three layers made of insulating resin (Three insulating resin layers 10, 8, and 11 from below, as illustrated in the drawing) are supplied from above the circuit substrate as base member of the circuit substrate and cured (Step 3).

It is preferably to use the vacuum laminating method or the vacuum pressing method as those methods for supplying insulating resin. However, the supplying method is not limited to those. Also, in case that there includes substance such as glass cloth or aramid film and so on in the insulating resin layer 8 disposed at the side face of the function element 1, which does not flow in pressing, a space is formed in advance in the insulating resin layer 8, which is provided with the shape identical to or larger than the outer shape of the function element 1, thereby enabling to protect the function element 1 from breaking by the substance with non flowing property in pressing.

For example, when resin includes epoxy, it is possible to supply and cure the resin by the vacuum pressing method in the range of peak temperatures 160 to 200° C. Also, in case that there includes substance with few flowability such as glass cloth or aramid film and so on in the insulating resin layer 8 disposed at the side face of the function element 1, it is preferable to form the space provided with the shape identical to the outer shape of the function element 1, or to form the space with the one side width larger than the outer shape of the function element 1 by the extent of about 0.1 to 1 mm.

In case that the insulating resin is supplied on the conductive wiring 103 and the support plate 101, it is possible to enhance the adhesion strength between the insulating resin layer and the conductive wiring 103, and the adhesion strength between the insulating resin layer and the support plate 101, by roughening the surfaces of the conductive wiring 103 and the support plate 101.

Also, when the support plate 101 is removed finally, combination and lamination orders of the insulating resin layers are properly adjusted such that the circuit substrate does not warp. Further, it is possible to enhance product reliability and to reduce the cost simultaneously by using a plural kinds of resin in combinations between the resin with high upper temperature limit and the resin with low upper temperature limit, and between the high cost resin and the low cost resin.

Also, it is possible to select resin having better adhesion property with the insulating resin layer 9 as the insulating resin layer 11, because in advance the electrode terminal 5 of the function element 1 is implemented in the insulating resin layer 9.

Also, it is possible to use the insulating resin layer 9 without forming on the function element 1 for the cost reduction, because the electrode terminal 5 of the function element 1 is immersed inside the insulating resin layer 11 in advance.

In the next, a via hole 66 is opened on the electrode terminal 5 of the function element 1 through the insulating resin layer 11 formed on the outermost face, using the apparatus for laser such as CO2 laser or UV-YAG laser and so on.

Also, at the same time a via hole 67 is opened on the conductive wiring 103 through the insulating resin layer 11 formed on the outermost face.

Then, resin residue inside the via holes 66 and 67 is removed by the desmear processing, and then the surfaces of the electrode terminal 5 and the conductive wiring 103 are washed with weak acid such as diluted sulfuric acid and so on (Step 4). In the case it is possible to use a drill to form the via hole 67.

For example, the via hole 66 can be formed with the dimension of the diameter of 10 to 200 μm, and the via hole 67 can be formed with the dimension of the diameter of 50 to 800 μm. In the case, the via holes 67 can be formed using the drill of diameter of 50 to 800 μm.

The resin core substrate mounting the function element as the circuit substrate in the prior art is not provided with the support plate 101 when it is manufactured. Therefore, there is a possibility that the function element 1 may be broken by stress added thereon when machining in case that the function element 1 is implemented in the vicinity of via hole, because rigidity of the resin is rather small for forming the via hole in the resin core substrate using the drill. Accordingly, there exists a problem that the via hole can not be disposed near the function element 1 and then the outer dimension of the circuit substrate becomes large. On the contrary, in the present invention the damage to the function element 1 which is implemented is reduced by means of usage of the support plate 101 with high rigidity even when the drill is used to form the via hole. Accordingly, it is possible to form the circuit substrate with high reliability and high wiring density, and further possible to reduce the outer dimension of the circuit substrate.

Then, copper or nickel and so on is clad through non electrolytic plating in the whole surface of the insulating resin layer 11 in which via holes 66 and 67 are opened. Then, plating resist is formed on the insulating resin layer 11 where copper or nickel and so on was clad through non electrolytic plating, and a conductive wiring 3 is formed by metallic plating. Further, conductive vias 6 and 7 are formed by metallic plating inside the via holes 66 and 67, and then the plating resist is removed, and the non electrolytic plating layer formed at portions other than the conductive wiring 3 is etched. (Step 5).

In the next, the conductive wiring 102 is exposed by etching the support plate 101 with acid or alkali. (Step 6). In the case, the height of the conductive wiring 102 is the same with that of the insulating resin layer 10 enclosing the outer circumference of the conductive wiring 102. Thus, the circuit substrate is formed as shown in FIG. 2(a). In the case, the conductive wiring 4 is formed with two layers of the conductive wirings 102, and 103. Further, in the next process the conductive wiring 102 is etched with the different chemical from that used in etching the support plate 101, and the conductive wirings 103 is exposed outside (Step 6), thereby forming the circuit substrate as shown in FIG. 2(b). In the case, since the surface of the conductive wirings 103 with exposed outside is disposed in the dimple, it is possible to use the insulating resin layer 10 as a solder resist layer.

For example, it is possible to plate the conductive wiring 102 with the thickness of 2 to 10 μm on the support plate 101 made of copper by the plating method. The support plate 101 is finally to be removed, and then in case of, for example, removing the support plate 101 through etching, the conductive wirings 102 can be formed with nickel, different from the support plate 101 made of copper such that the conductive wiring 102 may not dissolve in the etching solution. Also, the conductive wiring 103, for example, can be formed with the thickness of 5 to 20 μm of copper by plating using the plating method.

Then, the conductive wiring 102 made of nickel is exposed from the rear face by removing the support plate 101 with copper etching solution. In the case, the height of the conductive wiring 102 is in the same plane with the insulating resin layer 10. By this the circuit substrate is formed as shown in FIG. 2 (a). Also, it is possible to obtain the circuit substrate as shown in FIG. 2 (b), through etching the conductive wiring 102 made of nickel by nickel remover and so on different from chemical used for etching the support plate 101, and exposing the conductive wiring 103 made of copper on the surface. In the case, the height is inside than the insulating resin layer 10 by the extent of about 5 to 20 μm.

In case that the support plate 101 is made of material with rigidity such as glass, silicon, or ceramics and so on, even other than metal as copper and so on, it is possible to form a conductive wiring 4 through at first sputtering titanium on the surface and then sputtering or depositing copper, by the plating method using such a support plate 101. It is possible to use the polishing method and so on except etching in the removing process of the support plate 101.

In the circuit substrate formed as stated above, the conductive wirings 102 and 103 are formed on the support plate 101, and therefore, the height of the exposed face of the conductive wiring 4 consisting of two layers of the conductive wirings 102 and 103 or one layer of the conductive wiring 103 is in the same plane after the support plate 101 is removed. Accordingly, the high connection reliability can be obtained because the conductive wiring 4 can be used without forming the insulating resin layer such as solder resist and so on, as the electrode terminal used for implementing the semiconductor element with BGA package and so on in the fashion of surface mounting, thereby enabling to obtain an electronic device arrangement with high reliability.

Though the circuit substrate formed as stated above may be used as it is, it is also possible to use for implementing many devices by forming solder resist still having a given aperture on the surface of the circuit substrate with the thickness of 5 to 30 μm.

Also, by means of making the circuit substrate according to the present embodiment as a core substrate, it is possible to form further conductive wirings on both faces of the core substrate using the additive method, the semi additive method or the subtractive method.

Next, the fifth embodiment of the present invention will be explained.

FIGS. 6 (a) and (b) are schematic sectional views illustrating a circuit substrate according to the fifth embodiment of the present invention. In FIG. 6 the notation of the same constitutional element with that in FIGS. 1 to 5 is identical, and then the detailed explanation of such element is omitted. In the present embodiment the explanation is about that the function element 1 mounted on the circuit substrate has low heat generation when operating.

In the circuit substrate according to the second embodiment stated above, the conductive wiring 3 formed on the surface of the insulating resin layer 11 and connected through the via 6 to the electrode terminal 5 of the function element 1, and the conductive wiring 4 formed so as to expose its surface from the rear face of the insulating resin layer 10 are insulated by the insulating resin layers 10, 8 and 11. On the contrary, in the circuit substrate according to the present embodiment a part of the conductive wiring 3 and a part of the conductive wiring 4 are connected through a conductive via 7 formed by filling metal or conductive paste inside a via hole formed in the insulating resin layers 10, 8 and 11. The difference between the second and the present embodiments lies only in that point stated above, and the rest has the same structure with the second embodiment.

In the next, the performance of the circuit substrate according to the present embodiment, constituted as stated above will be explained.

In addition to the operation according to the second embodiment, the circuit substrate according to the present embodiment has the following operation and effect. By means of directly implementing the electronic components in the conducting wiring 3 disposed immediately above the function element 1, it is possible to shorten the distance between those electronic components and the electrode terminal 5 of the function element 1, thereby enabling to obtain the electronic device arrangement with the excellent and high speed electric property. In the case, because the conductive via 7 implements by the shortest way the connection between the conductive wiring 3 and the conductive wiring 4 in the front and rear faces of the circuit substrate, it is possible to laminate the circuit substrate vertically, thereby enabling to form a body of implementation with high density.

In the present embodiment, as shown in FIG. 6(a), it is not necessary that the face with exposed outside the conductive wiring 4 is disposed in the same plane with the rear face of the insulating resin layer 10, and only contacting the side face of the conductive wiring 4 to the insulating resin layer 10 is necessary. Namely, as shown in FIG. 6(b), the conductive wiring 4 may be immersed in the insulating resin layer 10 with the one face exposed outside.

Also, in the circuit substrate according to the present embodiment it is possible to use the insulating resin layer 9 without forming on the function element 1 for the cost reduction, because the function element 1 is contained inside the insulating resin layer 11.

Next, a manufacturing process of the circuit substrate according to the present embodiment will be explained.

FIG. 7 (a) to (j) are schematic views illustrating in stages the manufacturing process of the circuit substrate according to the present embodiment. In FIG. 7 the notation of the same constitutional element with that in FIGS. 1 to 6 is identical, and then the detailed explanation of the element is omitted.

First, resist for plating is supplied on the support plate 101. After exposing, developing and pattern forming, the conductive wirings 102 and 103 are formed by the plating method, the ink jet method and so on. Then, this resist for plating is peeled. (Step 1).

Then, the insulating resin layer 10 is supplied on the surface of the support plate 101 in which the conductive wirings 102 and 103 are formed, from above the conductive wirings 102 and 103. (Step 2). Because the support plate 101 is finally removed by etching and the insulating resin layer 10 is still disposed immediately below the function element 1 after removal of the support plate 101, it is possible to form the conductive wirings 102 and 103 such that those are provided with a given wiring pattern such as the BGA pad or the flip chip pad and so on. Also, it is preferably to use the vacuum laminator, the vacuum press machine, the roll coater, the spin coat or the curtain coat and so on for supplying insulating resin. However, the supplying means is not limited to those.

Then, an adhesion layer 2 is implemented on the insulating resin layer 10, with which the rear surface of the function element 1 with the electrode terminal 5 on the front surface is bonded on the insulating resin layer 10. (Step 3). As to the function element 1, it is possible to use the same provided with the electrode terminal 5 made of copper on the front surface and which base member are silicon, GaAg or glass. Also, the adhesion layer 2 can be formed by implementing epoxy system die attachment film with the thickness of 10 to 30 μm.

Then, an insulating resin layer 8 is supplied on the insulating resin layer 10 by the vacuum laminator or the vacuum press and so on such that the insulating resin layer 8 contacts with the side face of the function element 1. Further, the insulating resin layer 11 is supplied from above this insulating resin layer 8 and the function element 1 by the vacuum laminator or the vacuum press and so on (Step 4), thereby sealing the outer circumference of the function element 1 (Step 5).

In the case, at least three layers made of insulating resin (Three insulating resin layers 10, 8, and 11 as illustrated in the drawing) can be laminated. Accordingly, it is preferable for product reliability and for enhancement of workability in manufacturing that combination and lamination orders of the insulating resin layers are properly designed such that the circuit substrate does not warp when the support plate 101 is removed. Also, it is preferable to determine an arrangement for the insulating resin layers taking into account of adhesiveness between the material of the function element 1 and the insulating resin layers.

The insulating resin layers 10, 8 and 11 can be respectively formed in the range of 10 to 500 μm in thickness. Those values of thickness are variable corresponding to the thickness of the function element 1 built-in there. Further, in the insulating resin layers 10 and 11 near the front and rear surfaces of the circuit substrate, polyimide system resin or epoxy system resin can be used which has flexibility for preventing the bending stress from outside and the crack. For example, it is possible to form the insulating resin layers 10 with the thickness of 10 to 500 μm by supplying and curing insulating resin including ingredient of polyimide or epoxy on the support plate 101 on which the conductive wirings 102 and 103 are formed, using the vacuum laminator.

This insulating resin layer 10 is still disposed immediately below the function element 1 after removal of the support plate 101, it is possible to form the conductive wirings 102 and 103 such that those are provided with a given wiring pattern such as the BGA pad or the flip chip pad and so on.

By using insulating resin with the thermal expansion coefficient similar to the thermal expansion coefficient in the function element 1 for the insulating resin 8 disposed in circumference of the function element 1, it is possible to prevent a crack produced by the stress arising from the difference of the thermal expansion coefficient between the insulating resin layer 8 and the function element 1, thereby enabling to enhance the reliability of the circuit substrate.

The insulating resin layers 8 and 11 can be supplied by the vacuum laminator or the vacuum press. Also, in case that there includes substance with few flowability such as glass cloth or aramid film and so on in the insulating resin layer 8 disposed at the side face of the function element 1, it is preferable to form a space provided with the shape identical to the outer shape of the function element 1, or to form the space with the one side width larger than the outer shape of the function element 1 by the extent of about 0.1 to 1 mm. The number of combination of the insulating resin layer is not limited to three, and it is possible to pile up the insulating resin layer in multiple layers in the manufacturing process.

In the next process, as like the manufacturing process for the circuit substrate according to the fourth embodiment, a via hole is opened on the electrode terminal 5 of the function element 1 from the insulating resin layers 11 formed on the most outward surface using the apparatus for laser such as the CO2 laser or UV-YAG laser and so on. In the case, a via hole 67 may be opened at the same time from the insulating resin layers 11. But, in the manufacturing process for the circuit substrate according to the present embodiment, the case in which the via hole 67 is opened only on the conductive wiring 103 from the insulating resin layers 11, will be explained.

It is possible to use a drill for forming the via hole 67, but not limited to it. Then, resin residue inside the via holes 66 and 67 is removed by the desmear processing, and then the surfaces of the electrode terminal 5 and the conductive wiring 103 are washed with weak acid such as diluted sulfuric acid and so on (Step 6).

After that, it is possible to implement non electrolytic metallic plating. But, in case that the height of the via hole 67 is dramatically larger than the inner diameter of the same (Namely, the aspect ratio is larger), it is possible to directly plate the via hole 67 from the side of the support plate 101 using a metallic support plate 101, and supplying electric charge to the metallic support plate 101. Then, the metallic plating is implemented inside the via hole 67 up to the position higher than the surface of the insulating resin layers 11, then the surface of the insulating resin layers 11 is uniformly polished by buffing and so on, thereby disposing the height of the exposed conductive via 7 to the side of the insulating resin layers 11 in the same plane with the surface of the insulating resin layers 11. In addition, in case of buffing to the surface of the insulating resin layers 11 it is preferable to open the via hole 66 after buffing so as to prevent the dust made of organic substance from entering inside the via hole 66 when buffing.

Then, a via hole 66 is opened on the electrode terminal 5 of the function element 1 through the insulating resin layer 11 formed on the outermost face, using the apparatus for laser such as CO2 laser or UV-YAG laser and so on.

Then, resin residue inside the via holes 66 is removed by the desmear processing, and then the surface of the electrode terminal 5 is washed with weak acid such as diluted sulfuric acid and so on (Step 7).

Then, copper or nickel and so on is clad through non electrolytic plating in the whole surface of the insulating resin layer 11 in which via holes 66 is opened. Then, plating resist is formed on the insulating resin layer 11 where copper or nickel and so on was clad through non electrolytic plating, and a conductive wiring 3 is formed by metallic plating. Further, conductive via 6 is formed by metallic plating inside the via hole 66, and then the plating resist is removed, and the non electrolytic plating layer formed at portions other than the conductive wiring 3 is etched (Step 8). For example, in the circuit substrate according to the present invention the conductive wiring 4(Conductive wiring 104) and the conductive wiring 3 can be formed in the thickness of 5 to 20 μm by copper plating.

Then, the support plate 101 is removed (Step 9) in the same way as explained at step 6 of the manufacturing process for the circuit substrate according to the fourth embodiment stated above. As the result the circuit substrate according to the present embodiment is formed.

Further, the conductive wiring 103 is exposed outside (Step 10) in the same way as explained at step 7 of the manufacturing process for the circuit substrate according to the fourth embodiment stated above.

The conductive wiring 4 formed on the rear face with exposed is formed such that the surface exposed outside is immersed by the thickness of 20 or less than 20 μm, and the side face of the conductive wiring 4 contacts the insulating resin layer 11, thereby forming the circuit substrate according to the present embodiment.

The conductive via 6 which connects the conductive wiring 3 formed on the surface of the insulating resin layer 11 to the electrode terminal 5 formed on the surface of the function element 1, and the conductive via 7 which connects the conductive wiring 3 formed on the surface of the insulating resin layer 11 to the conductive wiring 4 formed with exposed on the rear surface of the insulating resin layer 10 can be formed by filling conductive paste including copper or Sn—Ag system powder inside the via holes 66 and 67.

Also, in case that ratio of the height to the inner diameter at upper portion of the conductive via 7 is larger than 1, it is possible to fill unleaded solder paste or conductive paste by the printed method.

For example, in the circuit substrate according to the present embodiment

It is possible to form on the support plate 101 the conductive wiring 102 made of nickel in the thickness of 2 to 20 μm and the conductive wiring 103 made of copper in the thickness of 5 to 30 μm by the printed method, using the support plate 101 made of copper with the thickness of 0.1 to 1.0 mm.

Also, the via hole 66 can be formed with the dimension of the diameter of 10 to 200 μm, and the via hole 67 can be formed with the dimension of the diameter of 50 to 800 μm.

Next, the sixth embodiment of the present invention will be explained.

FIG. 8 is a schematic sectional view illustrating a circuit substrate according to the sixth embodiment of the present invention. In FIG. 8 the notation of the same constitutional element with that in FIGS. 1 to 7 is identical, and then the detailed explanation of such element is omitted. In the present embodiment the explanation is about that the function element 1 mounted on the circuit substrate has low heat generation when operating.

In the circuit substrate according to the present embodiment, there are provided with a solder resist 51 to both faces of the circuit substrate and an opening portion 52 at the electrode terminal on the circuit substrate according to the fourth embodiment.

Then, the performance of the circuit substrate according to the present embodiment, constituted as stated in the above will be explained.

In the circuit substrate according to the present embodiment, there is provided with the solder resist 51 having the opening portion 52 only at the electrode terminal in order to prevent electric short between the conductive wirings when unleaded solder melts because of re-flow in implementing electronic component on the conductive wiring 3 in the form of surface mounting in the circuit substrate according to the fifth embodiment.

Also, since the face of the conductive wiring 4 with exposed outside is disposed in the same plane with the rear face of the insulating resin layer 10 or inside the rear face, it is not necessary to provide with the solder resist 51 on the side of the conductive wiring 4.

However, it is possible to provide with the solder resist 51 still on the side of the rear face which the conductive wiring 4 is formed so as to prevent the circuit substrate from warping. Accordingly, the circuit substrate according to the present embodiment has, in addition to the performance of the fifth embodiment stated above, the performances allowing to prevent electric short between the conductive wirings when unleaded solder melts because of re-flow in implementing electronic component on the conductive wiring 3 in the form of surface mounting in the circuit substrate, and to prevent the circuit substrate itself from warping.

Also, in the circuit substrate according to the present embodiment since the function is implemented inside the insulating resin layer 11, it is possible to use the insulating resin layer 9 without forming on the function element 1 for the cost reduction.

In the next, a manufacturing process of the circuit substrate according to the present embodiment will be explained.

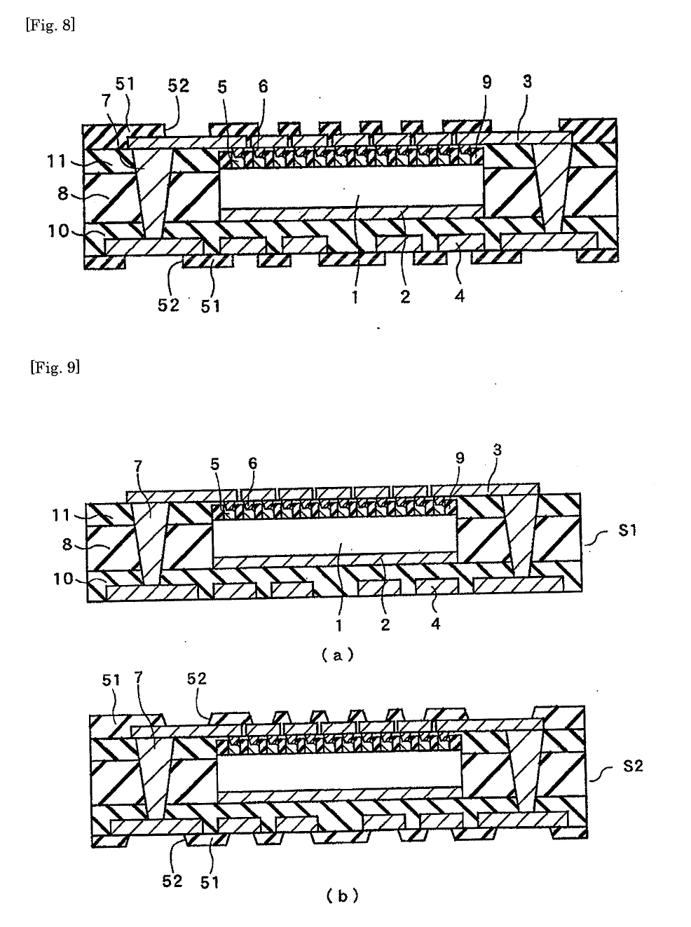

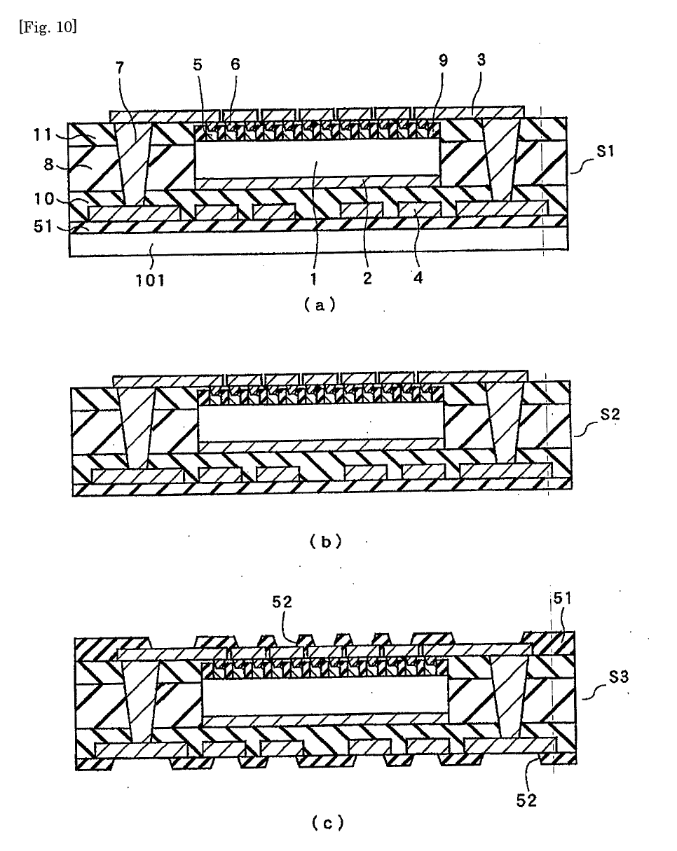

FIGS. 9 (a) and (b), and FIG. 10(a) to (c) are schematic views illustrating in stages the manufacturing process of the circuit substrate according to the present embodiment. In FIG. 9 and FIG. 10 the notation of the same constitutional element with that in FIGS. 1 to 8 is identical, and then the detailed explanation of the element is omitted.

The circuit substrate according to the fifth embodiment shown in FIG. 6(a) and (b) already explained above may be used as it is. However, in the manufacturing process for the circuit substrate according to the present embodiment, as shown in FIG. 9, it is possible to use first the circuit substrate according to the fifth embodiment as shown in FIG. 6(a) (Step 1), to further form a solder resist having a given aperture portion on the front and rear faces of the circuit substrate (Step 2), and to use for implementing multi devices. In the case the solder resist 51 may be formed only on one side of the circuit.

In the next, another manufacturing process of the circuit substrate according to the present embodiment will be explained.

As shown in FIG. 10, the manufacturing process is provided with processes of supplying in advance an insulating resin layer which becomes solder resist 51 later on the support plate 101, forming a conductive wiring 4 thereon, supplying the insulating resin layer 10 from above the solder resist in which the conductive wiring 4 is formed, mounting the function element 1 in the similar way with the step 3 to 8 in the manufacturing process of the fifth embodiment stated above and sealing the circumference of the function element 1 with the insulating resin layers 8, 10 and 11, connecting the conductive wiring 3 to the electrode terminal 5 of the function element 1 by the conductive via 6, and also connecting the conductive wirings 3 to 4 (Step 1).

Then, the support plate 101 is removed by the method of removal of the support plate 101 (Step 2) mentioned above, thereby exposing the insulating resin layer which will become the solder resist 51, and allowing to function as the solder resist 51 by providing with the aperture 52 with the laser and so on at a portion corresponding to electrode terminal of the electric component implemented thereafter. Further, the solder resist 51 with the thickness of 5 to 30 μm provided with the aperture 52 is formed on the front surface side of the conductive wiring 3 (Step 3). Thus, it is possible to obtain the circuit substrate provided with the solder resist 51 on the front and rear faces respectively.

For example, the circuit substrate according to the present embodiment can be provided with the aperture 52 at the portion of the electrode terminal through using epoxy system resin as the solder resist 51 and forming in the thickness of 10 to 30 μm. The conductive wiring 4 formed and exposed on the rear face of the insulating resin layer 10 can be formed by the process of implementing non electrolytic copper plating on the solder resist 51, patter-forming from above by plating resist, plating copper in the thickness of 5 to 30 μm, removing the plating resist and then removing the non electrolytic copper plating other than the conductive wiring 4. Also, the conductive wiring 4 can be formed such that the face exposed outside is disposed in the same plane with the rear face of the insulating resin layer 10 or is immersed in the depth of less than 20 μm.

In the case, it is not necessary to form the solder resist 51 on the rear face side of the circuit substrate. However, in the front surface of the circuit substrate it is preferable to provide with the solder resist 51 having the opening portion 52 only at the electrode terminal in order to prevent electric short between the conductive wirings when unleaded solder melts because of re-flow in implementing electronic component on the conductive wiring 3 in the form of surface mounting in the circuit substrate. Also, it is preferable to provide with the solder resist 51 on the rear face side of the circuit substrate to prevent the circuit substrate from warping.

Further, for example, the support plate 101 can be made of glass. By finally removing the support plate 101 with chemical or polishing, the insulating resin layer is exposed on the rear face, which will become solder resist 51, and allows to function as the solder resist 51 by providing with the via hole 52 with the laser and so on at a portion corresponding to electrode terminal of the electric component implemented thereafter.

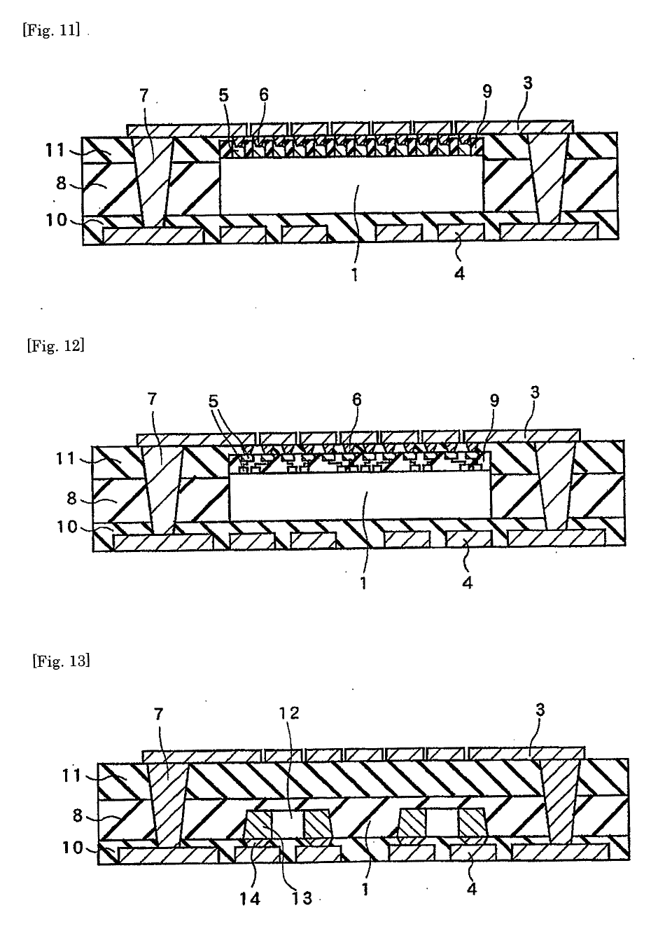

Next, the seventh embodiment according to the present invention will be explained. FIG. 11 is a schematic sectional view illustrating a circuit substrate according to the seventh embodiment of the present invention. In FIG. 11 the notation of the same constitutional element with that in FIGS. 1 to 10 is identical, and then the detailed explanation of the element is omitted. In the present embodiment the explanation is about that the function element 1 mounted on the circuit substrate has low heat generation when operating.

In the fifth embodiment stated above, the rear face of the function element 1 and the insulating resin layer 10 are bonded by the adhesion layer 2. On the contrary, in the present embodiment there exists no adhesion layer 2, namely, the rear face of the function element 1 directly contacts the insulating resin layer 10, that is the difference between the fifth embodiment and the present embodiment.

In the next, the performance of the circuit substrate according to the present embodiment, constituted as stated above will be explained.

In the circuit substrate according to the present embodiment, when forming the insulating resin layer 10, the rear face of the function element 1 is directly mounted on the insulating resin layer 10 in the state that such resin is semi hardened before calcification, and the insulating resin layer 10 and the function element 1 are bonded by pressing while adding heat. By heat addition flowability of the insulating resin layer 10 increases, and by disposing the function element 1 in a predefined position and pressing it the function element 1 and the insulating resin layer 10 are contacted adhesively, thereby mounting the function element 1 on the insulating resin layer 10.

Accordingly, the adhesion layer 2 with the thickness of about 10 to 40 μm is unnecessary, thereby enabling to make the circuit substrate thin.

In the present embodiment it is possible to dispose the resin layer 10 between the rear face of the function element 1 and the conductive wiring 4, thereby enabling to form fine wiring patterns of the conductive wiring 3 and the conductive wiring 4 on the front and rear faces of the circuit substrate immediately above and below the function element 1. Thus, it is possible to implement electronic components on the conductive wiring 3 and the conductive wiring 4 in the form of surface mounting, and the flip chip connection and so on of the semiconductor.

By this, it is possible to contribute to product miniaturization because area of the circuit substrate can be used effectively and also reduced when implementing.

Also, in the present embodiment the surface exposing outside the conductive wiring 4 is not necessary to be disposed in the same plane with the rear face of the insulating resin layer 10. Only contacting the side face of the conductive wiring 4 to the insulating resin layer 10 is necessary. Namely, the conductive wiring 4 may be immersed in the insulating resin layer 10 in the state that one face is exposed outside.

Also, in structure of the circuit substrate according to the present embodiment it is possible to use the insulating resin layer 9 without forming on the function element 1 for the cost reduction, because the function element 1 is contained inside the insulating resin layer 11.

Next, the eighth embodiment according to the present invention will be explained. FIG. 12 is a schematic sectional view illustrating a circuit substrate according to the eighth embodiment of the present invention. In FIG. 12 the notation of the same constitutional element with that in FIGS. 1 to 11 is identical, and then the detailed explanation of the element is omitted. In the present embodiment the explanation is about that the function element 1 mounted on the circuit substrate has low heat generation when operating.

In the circuit substrate according to the present embodiment, from the aspect of activity, a cylindrical shape made of copper called the copper post, or the conductive wirings of one or more than one layer and so on are formed inside the insulating resin layer 9, and through connecting the copper post or the conductive wirings and so on to the conductive via 6 the conductive wiring 3 formed on the insulating resin layer 11 and the electrode terminal 5 of the function element 1 are connected, that is the different point from the circuit substrate according to the seventh embodiment stated above, and the rest is similarly constituted. The copper post or the conductive wirings and so on are not limited in shape and material, and only necessary to have conductivity.

Then, the performance of the circuit substrate according to the present embodiment, constituted as stated above will be explained.

In case that the electrode terminal 5 is exposed from the insulating resin layer 9 in the circuit substrate according to the present embodiment, it is possible to see the electrode terminal 5 clearly when the function element 1 is mounted, which can be used as an alignment mark, thereby enabling to enhance the mounting accuracy.

Also, in case that the electrode terminal 5 is immersed inside the insulating resin layer 9, it is possible to protect the surface of the electrode terminal 5, thereby effecting workability well.

Also, in the present embodiment the surface exposing outside the conductive wiring 4 is not necessary to be disposed in the same plane with the rear face of the insulating resin layer 10. Only contacting the side face of the conductive wiring 4 to the insulating resin layer 10 is necessary. Namely, the conductive wiring 4 may be immersed in the insulating resin layer 10 in the state that one face is exposed outside.

Also, in structure of the circuit substrate according to the present embodiment it is possible to use the insulating resin layer 9 without forming on the function element 1 for the cost reduction when forming the copper post, because the function element 1 is contained inside the insulating resin layer 11.

Next, the ninth embodiment according to the present invention will be explained. FIG. 13 is a schematic sectional view illustrating a circuit substrate according to the ninth embodiment of the present invention. In FIG. 13 the notation of the same constitutional element with that in FIGS. 1 to 12 is identical, and then the detailed explanation of the element is omitted.

In the circuit substrate according to the present embodiment, a function element 12 having an electrode terminal 13 on both side faces is embedded in the insulating resin layer 8 on which the insulating resin layer 11 is formed, and further the conductive wiring 3 is formed on the surface of the insulating resin layer 11. Also, the insulating resin layer 10 having the conductive wiring 4 is formed on the rear surface of the function element 12. By a conductive via 14 formed with a via hole in which unleaded solder is filled, the conductive wiring 4 and the electrode terminal 13 provided in both side face of the function element 12 are connected.

Then, a part of the conductive wiring 3 and a part of the conductive wiring 4 are connected through a conductive via 7 formed by filling metal or conductive paste inside the via holes formed in the insulating resin layers 11, 8 and 10.

The surface of the conductive wiring 4 is in the same plane with that of the insulating resin layer 10, and the side face of the conductive wiring 4 contacts the insulating resin layer 10, thereby constituting the circuit substrate according to the ninth embodiment of the present invention.

In the circuit substrate according to the present embodiment, since in advance a via hole in the insulating resin layer 10 is formed using the laser beam and so on, at a portion corresponding to a location mounting an electrode terminal 13 of a function element 12, then a conductive via 14 is formed by printing unleaded solder, then the electrode terminal 13 of the function element 12 is disposed on the conductive via 14 and the reflow heat treatment is implemented, it is possible to connect the electrode terminal 13 of the function element 12 to the conductive wiring 4 through the conductive via 14 filled with unleaded solder.

Also, in case that photosensitive resin is used for the insulating resin layer 10 it is possible to form the via hole by exposing and developing.

In the present embodiment the conductive wiring 4 formed on the rear face with exposed can be formed such that the surface exposed outside is in the same plane with the rear face of the insulating resin layer 10 or disposed by the thickness of 20 or less than 20 μm.

For example, in the circuit substrate according to the present embodiment,

It is possible to use as the function element 12 a chip resister or a ceramics chip condenser formed in a shape which is provided with the electrode terminal 13 on the side face and can be easily implemented with the solder paste consisting of elements of Sn—Ag—Cu.

Also, the conductive wirings 3 and 4 can be formed by copper plating with the thickness of 2 to 20 μm.

The conductive via 7 which connects the conductive wiring 3 to the conductive wiring 4 can be formed by filling copper, nickel or conductive paste inside the via hole.

Also, the insulating resin layers 10, 8 and 11 can be respectively formed in the range of 5 to 80 μm in thickness. Those values of thickness are variable corresponding to the thickness of the function element 12 built-in there.

Also, since in advance the via hole in the insulating resin layer 10 is formed using the laser beam and so on, at the portion corresponding to the location mounting the electrode terminal 13 of the function element 12, then the conductive via 14 is formed by printing unleaded solder, then the electrode terminal 13 of the function element 12 is disposed on the conductive via 14 and the reflow heat treatment at the peak temperature of 240° C. is implemented, it is possible to connect the electrode terminal 13 of the function element 12 to the conductive wiring 4 through the conductive via 14 filled with unleaded solder.

Also, in case that photosensitive resin of epoxy system or polyimide system is used for the insulating resin layer 10 it is possible to form the via hole by exposing and developing. Forming the via hole by exposing and developing can reduce any damages to the insulating resin layer because the insulating resin layer is not heated as when processing by the laser beam.

In the next, the performance of the circuit substrate according to the present embodiment, constituted as stated above will be explained.

In the present embodiment there is no limitation in the number and the sort of the insulating resin layer. (Three layers of the resin layer 8, the resin layer 10 and the resin layer 11 are used as illustrated in drawings)

Thus, it is possible to enhance the reliability for the circuit substrate, since a plurality of layers are used as the insulating resin layer, the resin with strong flexibility is used for the resin layers 10 and 11 near the front and rear of the circuit substrate, which prevents bending stress from outside and crack generation, the insulating resin 8 disposed in the vicinity of the function element 12 is used as the insulating resin which thermal expansion coefficient is similar to that of the function element 12, and the crack is prevented which is arising from stress generated by the difference of the thermal expansion coefficient between the insulating resin 8 and the function element 12.

Further, it is possible to enhance product reliability and to reduce the cost simultaneously by using a plural sorts of resin in combinations between the resin with high upper temperature limit and the resin with low upper temperature limit, and between the high cost resin and the low cost resin.

In the circuit substrate it is possible to easily use a cheap function element sold in the market for the surface mounting, and also it is possible to reduce the number of mounting parts on the surface of the circuit substrate, and to scale down the area of the circuit substrate because chip resister or ceramics chip condenser and so on can be embedded inside the circuit substrate.

Next, the tenth embodiment of the present invention will be explained.

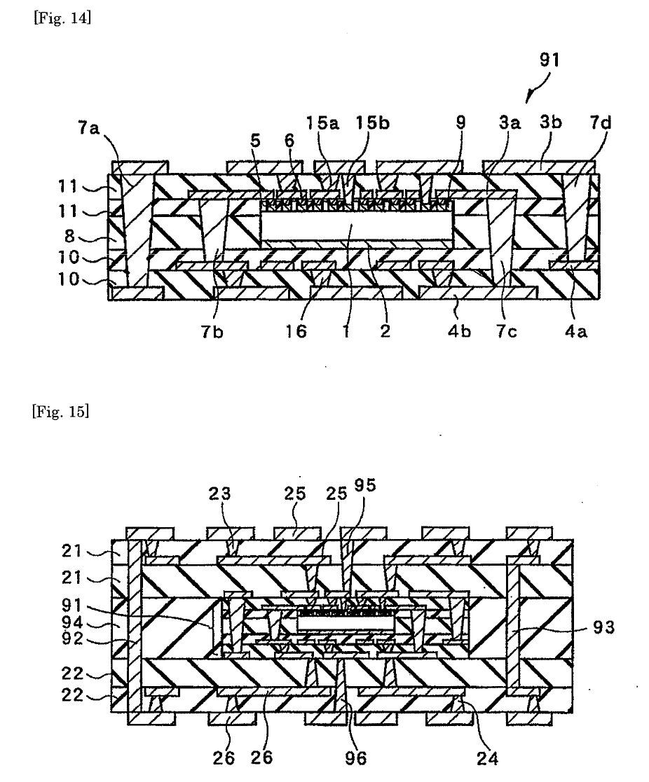

FIG. 14 is a schematic sectional view illustrating a circuit substrate according to the sixth embodiment of the present invention. In FIG. 14 the notation of the same constitutional element with that in FIGS. 1 to 13 is identical, and then the detailed explanation of such element is omitted. In the present embodiment there is no limitation in the number and the sort of the insulating resin layer. FIG. 14 illustrates the insulating resin layer with five layers and three sorts.

In the circuit substrate according to the present embodiment, the front surface side of the function element 1 with the electrode terminal 5 is sealed with the insulating resin layer 11, the rear surface of the function element 1 and the insulating resin layer 10 are bonded with the adhesion layer 2 and the insulating resin layer 8 seals between the insulating resin layer 11 and the insulating resin layer 10 provided with a conductive wiring 4a. And, a conductive wiring 3a formed on the front surface of the insulating resin layer 11 and the electrode terminal 5 of the function element 1 are connected through the conductive via 6, and then, on the insulating resin layer 11 provided with the conductive wiring 3a thereon, further insulating resin layer 11 provided with a conductive wiring 3b thereon is formed. Then, this conductive wiring 3b and the conductive wiring 3a are connected through a conductive via 15a, and the conductive wiring 3b and the electrode terminal 5 of the function element 1 are connected through a conductive via 15b.

Also, a conductive wiring 4a formed with exposed on the rear face of the insulating resin layer 10 and the conductive wiring 3a are connected through a conductive via 7b, and the conductive wiring 3b and the conductive wiring 4a are connected through a conductive via 7d.

Also, under the insulating resin layer 10 provided with the conductive wiring 4a formed on the rear face, further insulating resin layer 10 provided with a conductive wiring 4b formed with exposed on the rear face is formed. Then, this conductive wiring 4b and the conductive wiring 4a are connected through a conductive via 16, and the conductive wiring 4b and the conductive wiring 3a are connected through a conductive via 7c. Also, further the conductive wiring 4b and the conductive wiring 3b are connected through a conductive via 7a. And, the face of the conductive wiring 4b with exposed outside is in the same plane with the rear face of the insulating resin layer 10 disposed at the lowermost face, and the side face of the conductive wiring 4b contacts the insulating resin layer 10, thereby constituting the circuit substrate 91 according to the present embodiment.

In the present embodiment, there is formed the conductive wiring provided with two layers up and down the function element 1. Those four layers of the conductive wiring are connected therebetween by the conductive via filled with metal such as copper, nickel, gold, silver and so on, or conductive paste and so on.

Also, since the tapers of all conductive via are directed to the same direction, the inner diameter of all conductive vias 6 and 7 becomes small at the rear side of the circuit substrate, and becomes large at the front side of the circuit substrate.

Then, the performance of the circuit substrate according to the present embodiment, constituted as stated above will be explained.

In the present embodiment there are illustrated the insulating resin layer with five layers and three sorts of the resin layer 8, the resin layer 10 and the resin layer 11 which are used.

However, it is possible to form with all different sort of resin the insulating resin layer between each conductive wiring disposed up and down the function element 1.

Thus, it is possible to enhance the reliability for the circuit substrate, since a plurality of layers are used as the insulating resin layer, the resin with strong flexibility is used for the resin layers 10 and 11 near the front and rear of the circuit substrate, which prevents bending stress from outside and crack generation, the insulating resin 8 disposed in the vicinity of the function element 1 is used as the insulating resin which thermal expansion coefficient is similar to that of the function element 1, and the crack is prevented which is arising from stress generated by the difference of the thermal expansion coefficient between the insulating resin 8 and the function element 1.

Also, it is possible to enhance product reliability and to reduce the cost simultaneously by using a plural sorts of resin in combinations between the resin with high upper temperature limit and the resin with low upper temperature limit, and between the high cost resin and the low cost resin.

Further, it is possible to connect using the conductive via 7a, 7b, 7c, 7d, from conductive wirings provided in all insulating resin layers to a given conductive wiring, in the multi layered conductive wiring disposing up and down the function element 1. Thus, it is possible to enhance freedom in circuit design and to laminate the circuit substrate vertically, thereby enabling to form a body of implementation with high density.

As like a conductive via 15b, through providing with the conductive via which is connected directly to the conductive wiring 3b on the surface of the circuit substrate immediately above the function element 1, it is possible to make electrical connections in the short distance with capacitors or semiconductor devices and so on connected by solder or gold wires, which are disposed outside the circuit substrate 91, using the circuit substrate 91 according to the present embodiment. Also, it is possible to implement electronic components on the conductive wiring provided on the front and rear faces of the circuit substrate in the form of surface mounting, and the flip chip connection and so on.

Thus, it is possible to contribute to product miniaturization because area of the circuit substrate can be used effectively and also reduced when implementing.

Also, in the present embodiment the surface exposing outside the conductive wiring 4b is not necessary to be disposed in the same plane with the rear face of the insulating resin layer 10. Only contacting the side face of the conductive wiring 4b to the insulating resin layer 10 is necessary. Namely, the conductive wiring 4b may be immersed in the insulating resin layer 10 in the state that one face is exposed outside.

Also, in structure of the circuit substrate according to the present embodiment it is possible to use the insulating resin layer 9 without forming on the function element 1 for the cost reduction, because the function element 1 is contained inside the insulating resin layer 11.

For example, in the circuit substrate according to the present embodiment, as the function element 1, it is possible to use the function element which is provided with the electrode terminal 5 made of copper on the surface, and which base member can be GaAs or silicon. Also, it is possible to form the conductive wirings 3a, 3b, 4a and 4b by copper plating with the thickness of 2 to 20 μm. Also, it is possible to form the conductive vias 6, 7a to 7d, and 15a to 15d by the processing of copper plating inside the via holes.

The insulating resin layers 10, 8 and 11 can be respectively formed in the range of 10 to 80 μm in thickness. Those values of thickness are variable corresponding to the thickness of the function element 1 built-in there.

Next, the eleventh embodiment according to the present invention will be explained. FIG. 15 is a schematic sectional view illustrating a circuit substrate according to the ninth embodiment of the present invention. In FIG. 15 the notation of the same constitutional element with that in FIGS. 1 to 14 is identical, and then the detailed explanation of the element is omitted.

In the present embodiment there is provided with an insulating resin layer 94 on the side face of the circuit substrate 91 according to the tenth embodiment stated above. Further, there is provided with at least one of an insulating resin layer 21 having a conductive wiring 25 on the front face, on the upper face of the circuit substrate 91 (Two layers in the illustration). Also, on the under surface of the circuit substrate 91 there is formed at least one of an insulating resin layer 22 having a conductive wiring 26 on the rear face (Two layers in the illustration).

Also, the conductive wirings formed in each insulating resin layer are connected by conductive vias 23 and 24 which connects between the conductive wirings through one layer of the insulating resin layers, and are connected by conductive vias 95 and 96 which connects between the conductive wirings through two layers of the insulating resin layers.

Also, the uppermost and the lowermost conductive wirings which interleave the circuit substrate 91 are connected by conductive vias 92 and 93, thereby constituting the circuit substrate according to the present embodiment.

The conductive wiring formed on the insulating resin layers can be formed using the additive construction method, semi additive construction method or the subtractive construction method and so on. Also, the conductive wiring layers consisting of the insulating resin layer 21 and the conductive wiring 25, and the insulating resin layer 22 and the conductive wiring 26 can be constituted with a given number of the layer.

Then, the performance of the circuit substrate according to the present embodiment, constituted as stated above will be explained.

In the circuit substrate according to the present embodiment, since the pitch of the conductive wirings formed on the frontmost and the rearmost surfaces are enlarged than the pitch disposed in the electrode terminal 5 of the function element 1 which the circuit substrate 91 contains therein, it is possible to form much better products even in case that the positioning accuracy for mounting and the aperture position accuracy by the laser beam are lower than those in the circuit substrate 91 containing the function element 1. Thus, it is advantageous that for the purpose of still high multi layers the circuit substrate 91 is contained in the circuit substrate.

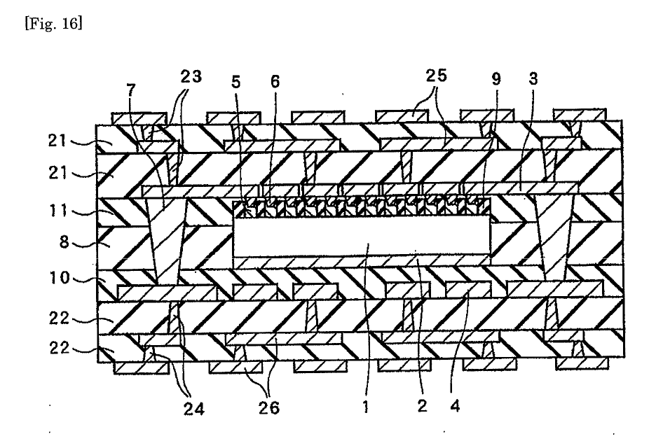

Next, the twelfth embodiment according to the present invention will be explained. FIG. 16 is a schematic sectional view illustrating a circuit substrate according to the ninth embodiment of the present invention. In FIG. 16 the notation of the same constitutional element with that in FIGS. 1 to 15 is identical, and then the detailed explanation of the element is omitted.

In the present embodiment, the circuit substrate according to the fifth embodiment stated above is used as a core substrate. On the upper surface of the core substrate, plural layers of the insulating resin layer 21 (Two layers in the illustration) are laminated, which is provided with the conductive wiring 25 formed in the surface by the additive construction method, semi additive construction method or the subtractive construction method, and the conductive wiring on wiring provided in different insulating resin layer 21 are connected by the conductive via 23. Also, on the under surface of the core substrate, plural layers of the insulating resin layer 22 (Two layers in the illustration) are laminated, which is provided with the conductive wiring 26 formed in the surface by the additive construction method, the semi additive construction method or the subtractive construction method, and the conductive wiring on wiring provided in different insulating resin layer 22 are connected by the conductive via 24, thereby constituting the circuit substrate according to the present embodiment

In the next, the performance of the circuit substrate according to the present embodiment, constituted as stated above will be explained.

The circuit substrate according to the fourth embodiment stated above is used as a core substrate. On the core substrate the insulating resin layer and the wiring layer are laminated, whereby it is possible to easily enlarge the arrangement of the electrode terminal 5 of the recent miniaturized function element 1 as it comes up to the surface of the circuit substrate. Further, it is possible to perform at different places a process for making the circuit substrate of the fourth embodiment stated above as the core substrate in the present embodiment and a process for building up thereafter the wiring layers formed on both faces of the core substrate in the present embodiment.

Since no equipment or facility is necessary at the place to build up the wiring layers, it is possible to reduce the production cost.

Then, the manufacturing process of the circuit substrate according to the present embodiment will be explained.

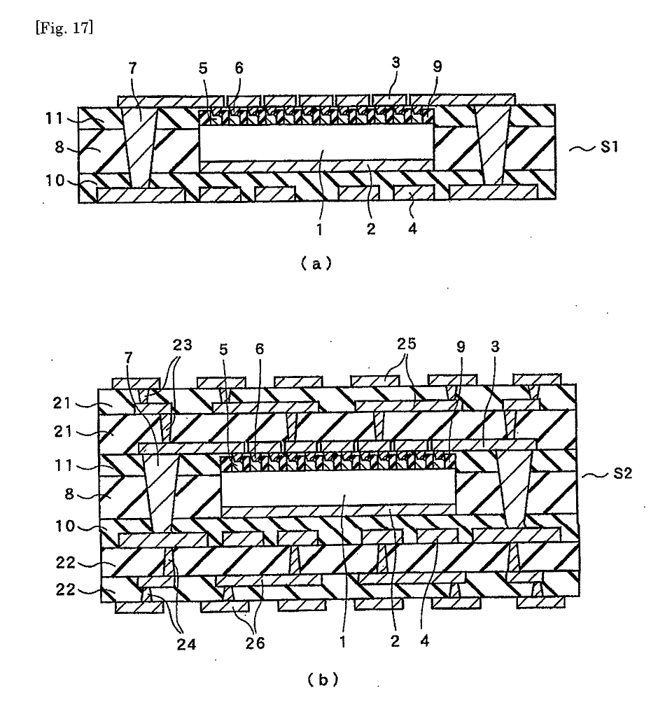

FIGS. 17 (a) and (b) are schematic views illustrating in stages the manufacturing process of the circuit substrate according to the present embodiment. In FIG. 17 the notation of the same constitutional element with that in FIGS. 1 to 16 is identical, and then the detailed explanation of the element is omitted.

As shown in FIG. 17, the manufacturing process of the circuit substrate according to the present embodiment includes the steps of

using first the circuit substrate according to the above fifth embodiment shown in FIG. 6(a) (Step 1),

forming the insulating resin layer 21 on the front surface of the circuit substrate,

forming the conductive via 23 on the insulating resin layer 21,

forming the conductive wiring 25 on the conductive via 23 by the additive construction method, the semi additive construction method or the subtractive construction method,

further forming the insulating resin layer 21 on the conductive wiring 25, and

repeating the above steps in the same way, thereby laminating conductive wiring layers consisting of the conductive wiring 25 and the insulating resin layer 21 by the given number of layers.

Also, as to the side of the rear surface of the circuit substrate, the process in the same way includes the steps of

forming the insulating resin layer 22 on the rear surface of the circuit substrate,

forming the conductive via 24 under the insulating resin layer 21,

forming the conductive wiring 26 under the conductive via 24 by the additive construction method, the semi additive construction method or the subtractive construction method,

further forming the insulating resin layer 21 under the conductive wiring 26, and

repeating the above steps in the same way, thereby laminating conductive wiring layers consisting of the conductive wiring 26 and the insulating resin layer 21 by the given number of layers (Step 2).

Thus, the circuit substrate according to the present embodiment can be obtained.

For example, it is possible to form the conductive wirings 25 and 26 of the circuit substrate according to the present embodiment with the thickness of 5 to 25 μm using the semi additive construction method.

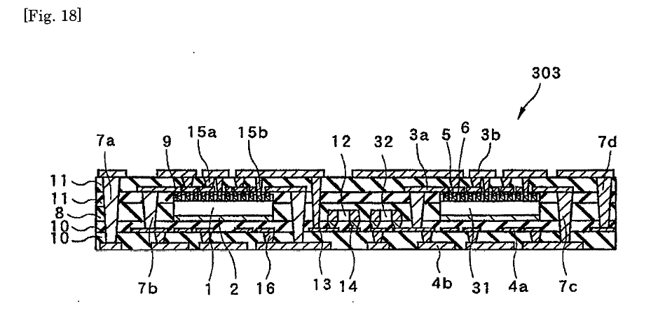

Then, the thirteenth embodiment according to the present invention will be explained. FIG. 18 is a schematic sectional view illustrating a circuit substrate according to the present embodiment. In FIG. 18 the notation of the same constitutional element with that in FIGS. 1 to 17 is identical, and then the detailed explanation of the element is omitted.

In the circuit substrate according to the present embodiment, one or more than one sorts and plural members of the function element formed with the electrode terminal 5 on the front face (Two sorts of the function elements 1 and 31 with each one by one are illustrated in the drawing) are bonded with the adhesion layer 2 on the insulating resin layer 10 formed with the conductive wiring 4a exposed on the rear face. Also, the function elements 12 and 32 which are provided with the electrode terminal on the side face, and are the chip parts such as the resister or the capacitor and so on are arranged in the horizontal direction. Those function elements 12 and 32 are electrically and structurally connected to the conductive wiring 4a through the conductive via 14 filled with unleaded solder therein. There are formed on the upper faces of those function elements 1, 31, 12 and 32, two layers of the insulating resin layer 11 with the conductive wiring on the surface, and also, there are formed on the lower face, two layers of the insulating resin layer 10 with the conductive wiring 4 exposed on the rear face.

A conductive wiring 3b and a conductive wiring 3a are connected by a conductive via 15a, and the conductive wiring 3b and the electrode terminal 5 of the function elements 1 are connected by a conductive via 15b. Also, a conductive wiring 4b and a conductive wiring 4a are connected by a conductive via 16.

The conductive wiring 4a and the conductive wiring 3a are connected by a conductive via 7b, the conductive wiring 3b and the conductive wiring 4a are connected by a conductive via 7d, the conductive wiring 4b and the conductive wiring 3a are connected by a conductive via 7c, and also, the conductive wiring 4b and the conductive wiring 3b are connected by a conductive via 7a.

By means of those, each wiring layer and each function element are electrically connected so as to constitute the target circuit.

Also, the tapers of all conductive via are directed to the same direction. Therefore, the inner diameter of all conductive via becomes small at the face on which the conducting wiring 4a is formed, and becomes large at the opposite face. Thus, the circuit substrate 303 according to the present embodiment is constituted.

Then, the performance of the circuit substrate according to the present embodiment, constituted as stated above will be explained.

As stated above, since different kinds and plural members of the function elements are arranged in the horizontal direction, and then the circuit substrate is formed by electrically connecting them, it is possible to implement parts within the circuit substrate, namely, in the form of built-in, which are implemented on both side faces of the circuit substrate in the prior art. Accordingly, it is possible to implement the parts in the circuit substrate much more than before. Also, in case that the number of the parts to be implemented in the circuit substrate is the same with that in the prior art, it is possible to scale down the area of the circuit substrate, thereby enabling to achieve miniaturization of the product.

Also, in the present embodiment, the surface exposing outside the conductive wiring 4b is not necessary to be disposed in the same plane with the rear face of the insulating resin layer 10. Only contacting the side face of the conductive wiring 4b to the insulating resin layer 10 is necessary. Namely, the conductive wiring 4b may be immersed in the insulating resin layer 10 in the state that one face is exposed outside.

Then, the manufacturing process of the circuit substrate 303 according to the present embodiment will be explained.

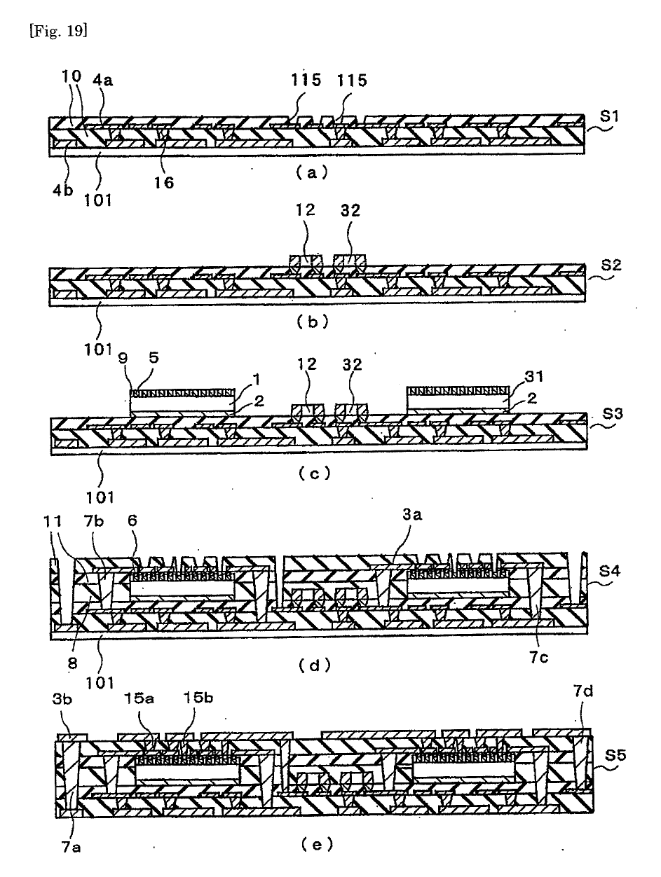

FIG. 19 (a) to (e) are schematic views illustrating in stages the manufacturing process of the circuit substrate according to the present embodiment. In FIG. 19 the notation of the same constitutional element with that in FIGS. 1 to 18 is identical, and then the detailed explanation of the element is omitted.

The process includes the steps of:

first, forming the conductive wiring 4b on the support plate 101,

then supplying the insulating resin layer 10 from above the conductive wiring 4b on the surface of the support plate 101 on which the conductive wiring 4b is formed,

then, forming the via hole in the insulating resin layer 10 using the laser beam and so on,

forming the conductive via 16 by filling the inside of this via hole using metallic plating method and so on,

and forming the conductive wiring 4a on the insulating resin layer 10 using the semi additive method and so on.

Further, through repeating those steps, laminating a plurality of the conductive wiring layers (two layers are illustrated), and

forming a via hole 115 on the uppermost layer of the insulating resin layer 10 (Step 1).

Then, supplying unleaded solder paste to the via hole 115 by printed method or dispenser,

disposing the function elements 12 and 32 provided with the electrode terminal at the side face on the unleaded solder paste,

melting the unleaded solder paste to form the conductive via 14,

then, connecting the function elements 12 and 32 to the conductive wiring 4a lying immediately below them by the conductive via 14 (Step 2).

In the case, in the present invention it is possible to use paste resisters or paste capacitors and so on with the equal performance, instead of the function elements 12 and 32, wherein it is possible to obtain the same effect when the function elements are mounted by printed method without mounting the function elements.

In cases that solder pasties used as stated above, flux residue is washed by comical. Then, a plurality of the function elements provided with the electrode terminal and the insulating resin layer on the surface (two function element 1 and 31 are illustrated) are arranged and bonded with the adhesion layer 2 (Step 3). In the case the kind and the outer shape of the function element are arbitrary.

Then, in the next step, sealing the outer circumference of the function element 1 and 31 with the insulating resin layer 8 and 11, then, forming the via hole in the insulating resin layer 11 using the laser beam and so on, forming the conductive via 6, 7b and 7c by filling the inside of this via hole using metallic plating method and so on, and forming the conductive wiring 3a on the insulating resin layer 11 using the additive method, the semi additive method or subtractive method.

Through this, connecting the conductive wiring 3a to the electrode terminal of the function element by the conductive via 6, and further connecting the conductive wiring 3a to the conductive wiring 4a by the conductive via 7b, and connecting the conductive wiring 3a to the conductive wiring 4b by the conductive via 7c, and then, through repeating those steps, laminating the conductive wiring layer by the given number of layer.

Thus, the via hole is formed using the laser beam and so on from the insulating resin layer 11 formed at the uppermost layer of insulating resin layers to the given conductive wiring and electrode terminal (Step 4), then forming the conductive vias 7a, 7b, 15a and 15b by filling the inside of this via hole using metallic plating method and so On.

Then, the conductive wiring 3b is formed on the insulating resin layer 11 formed at the uppermost layer using the additive method, the semi additive method or subtractive method.

The conductive wiring 3b formed on the surface of the insulating resin layer 11 of the uppermost layer and the conductive wiring 4b are connected by the conductive via 7a, and the conductive wiring 3b and the conductive wiring 4a are connected by the conductive via 7d. Then, the support plate 101 is removed by the method stated above for removing the support plate 101 (Step 5).

Through connecting between the conductive wiring 3b and the conductive wiring 4b formed on the front and rear faces of the circuit substrate 303 obtained by the method stated above, it is possible to connect in the shortest way between the electronic components implemented in the front and rear faces of the circuit substrate 303, and between those components and the function element 1, thereby enabling to obtain the circuit substrate less in dielectric loss and excellent in high speed electric characteristics.

Also, the circuit substrate 303 obtained by the method stated above can be used as it is. However, it is possible to use for multi device implementation by further forming solder resist having a given aperture. Also, by means of making the circuit substrate shown in FIG. 19(e) as a core substrate, it is possible to form further conductive wiring layers on both faces of the core substrate using the additive method, the semi additive method or the subtractive method.

For example, in the circuit substrate 303 according to the present embodiment, as the function elements 1 and 32 it is possible to use such a function element of the type which is provided with the electrode terminal 5 made of copper on the surface and is made of silicon, and which is made of GaAs.

Also, as the function elements 1 and 32 it is possible to use the chip parts such as resisters or capacitors, which are provided with the electrode terminal 5 on the side face.

Also, it is possible to use organic resin as the adhesion layer 2, and to form in the thickness of 5 to 30 μm.

Also, it is possible to use unleaded solder of Sn—Ag—Cu system as the unleaded solder paste supplied to the via hole 115.

Also, it is possible to respectively form copper in the thickness of 2 to 20 μm as the conductive wirings 3a, 3b, 4a and 4b.

Further, it is possible to form using the copper plating method as the conductive vias 6, 7a, 7b, 7c, 7d, 14, 15a, 15b and 16.

Also, for example, in the circuit substrate 303 according to the present embodiment, it is possible to form the conductive wiring 103 made of copper in the thickness of 2 to 30 μm using the support plate 101 made of nickel with the thickness of 0.1 to 1.0 mm.

Further, it is possible to use epoxy system resin as the insulating resin layer 10, and to form on the insulating resin layer the conductive wiring 4 made of copper by the semi additive method.

Also, it is possible to supply unleaded solder of Sn—Ag—Cu system to the portion corresponding to the via hole 115 by printed method, and it is possible to implement the function element 12 and 32 by disposing the function element 12 and 32, using reflow furnace or hot plate and so on, and melting at the peak temperature of 240 to 260° C. It is preferable to wash the flux residue with “PINE ALPHA” (trade name) made of Arakawa Chemical Industries, Ltd. or ethanol and so on, when used solder paste.

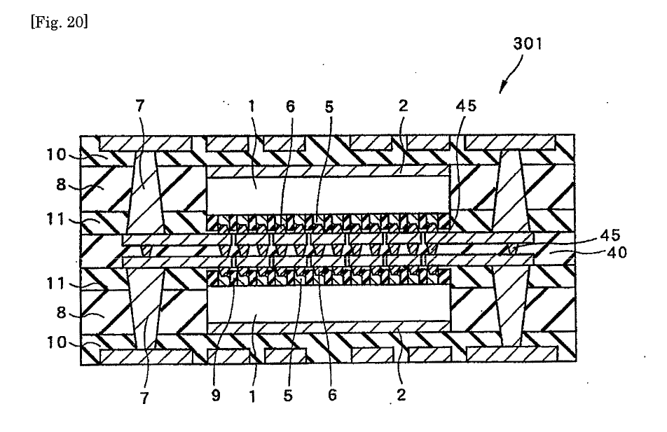

Next, the circuit substrate according to the fourteenth embodiment of the present invention will be explained. FIG. 20 is a schematic sectional view illustrating a circuit substrate 301 according to the present embodiment. In FIG. 20 the notation of the same constitutional element with that in FIGS. 1 to 19 is identical, and then the detailed explanation of the element is omitted.

In the present embodiment, two circuit substrates according to the fifth embodiment stated above, as shown in FIG. 6(a) are used with disposed above and below. The circuit substrate according to the fifth embodiment stated above, which is disposed above is disposed with the state upside down in respect to the state shown in FIG. 6(a). By means of the insulating connection due to the adhesion layer 40 made of insulator and the conductive connection due to the conductive via 45 formed through the front and rear face of the adhesion layer 40, which is embedded with the conductive paste, the function element 1 contained within the circuit substrate disposed at the upper side and the function element 1 contained within the circuit substrate disposed at the lower side are connected, whereby two circuit substrates are laminated in the vertical direction. Thus, the circuit substrate 301 according to the present embodiment is constituted.

As the adhesion layer 40, it is possible to use the glass cloth-containing epoxy resin, usually called prepreg or aramide non woven sheet-containing epoxy resin and with the thickness of 20 to 80 μm.

Also, it is possible to form the conductive via 45 with unleaded solder paste which includes powder made of element such as Sn, Ag, Bi and Cu and so on. Also, it is possible to decide composition in accordance with the reflow temperature. Also, when the conductive via has the inner diameter of less than 100 μm, it is preferable to decide the particle diameter of the powder to be less than 10 μm, which is made of element such as Sn, Ag, Bi and Cu and so on.

Also, the via hole 45 formed through between the front and rear faces of the adhesion layer 40 can be formed by the following steps, namely, for example, in the state that the protective films such as PET (Poly Ethylene Terephthalate) or PEN (Poly Ethylene Naphthalate) and so on are laminated on both sides of the adhesion layer 40, perforating the via hole completely to the other side by means of the laser beam of CO2 or UV-YAG and so on, or the drill, then filling the powder including elements such as Sn, Cu, Bi, Ni, Fe, Ge and Mg and so on inside the via hole through printing solder paste or conductive paste and so on, onto the protective films, and then removing the films laminated on both sides of the adhesion layer 40.

Also, it is possible to print solder paste or conductive paste and so on using a metal mask or a screen mask, without use of the protective films.

Also, it is possible to fill the powder including elements such as Sn, Cu, Bi, Ni, Fe, Ge and Mg and so on inside the via hole.

Then, the performance of the circuit substrate according to the present embodiment, constituted as stated above will be explained.

As mentioned above, since the two circuit substrates, each of which contains the function element 1 therein, are connected such that the faces of the electrode terminal of the function element are disposed with face to face, it is possible to obtain the electric connection with the shortest way between the two function elements, thereby enabling to obtain the circuit substrate with excellent high speed electric characteristics. Also, in the constitution of the circuit substrate according to the present embodiment, since the conductive wiring 4 with the uniform height is exposed outside on both sides of the circuit substrate, it is possible to keep the distance between the LSI (Large Scale Integration) chips and the conductive wirings to be constant, thereby enabling to effect the connection with high reliability, in case that the circuit substrate according to the present embodiment is used for the flip chip connection in the semiconductor.

Also, in the present embodiment it is illustrated that the two circuit substrates containing the same function element 1 are laminated in the vertical direction. However, without such a limitation, it is possible to laminate the two circuit substrates containing different kind of function elements therein.

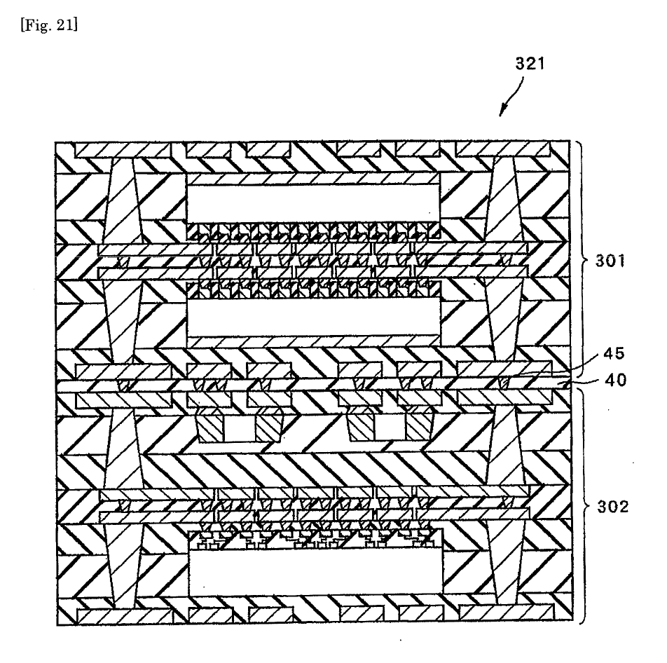

Next, the circuit substrate according to the fifteenth embodiment of the present invention will be explained. FIG. 21 is a schematic sectional view illustrating a circuit substrate according to the present embodiment. In FIG. 21, the notation of the same constitutional element with that in FIGS. 1 to 20 is identical, and then the detailed explanation of the element is omitted.

In the present embodiment, the circuit substrate according to the eighth embodiment stated above and the circuit substrate according to the ninth embodiment stated above are used in the arrangement up and down. On the circuit substrate according to the eighth embodiment, there is disposed the adhesion layer 40 made of insulator, with the conductive via 45 perforated between the front and rear faces, and on the adhesion layer 40 there is disposed the circuit substrate according to the ninth embodiment with the state upside down in respect to the state shown in FIG. 12.

By means of the insulating connection due to the adhesion layer 40 made of insulator and the conductive connection due to the conductive via 45 formed through the adhesion layer 40, which is embedded with the conductive paste, the conductive wiring 3 of the circuit substrate according to the eighth embodiment and the conductive wiring 3 of the circuit substrate according to the ninth embodiment are connected, whereby the function element contained within the circuit substrate according to the eighth embodiment and the function element contained within the circuit substrate according to the ninth embodiment are electrically connected. Thus, the circuit substrate 302 is constituted, in which the circuit substrate according to the eighth embodiment and the circuit substrate according to the ninth embodiment are vertically laminated.

There is further disposed the adhesion layer 40 made of insulator and provided with the conductive via 45 perforated through the front and rear faces, and on the adhesion layer 40 there is disposed the circuit substrate 301 according to the fourteenth embodiment.

By means of the insulating connection due to the adhesion layer 40 made of insulator and the conductive connection due to the conductive via 45 formed through the adhesion layer 40, which is embedded with the conductive paste, the conductive wiring provided in the most outward face of the circuit substrate 302 and the conductive wiring provided in the lowermost face with exposed are connected. Thus, the circuit substrate 301 is constituted, wherein the circuit substrate according to the eighth embodiment, the circuit substrate according to the ninth embodiment and the circuit substrate 301 according to the fourteenth embodiment are vertically laminated.

Then, the performance of the circuit substrate according to the present embodiment, constituted as stated above will be explained. In the circuit substrate 321 according to the present embodiment it is possible to laminate plural kinds of function elements and also to shorten the wiring length between each function element. Thus, it is possible to solve the problem that in the prior art the electronic components have to be implemented only in the two dimensional directions, and enables to implement the components with high integration in the form of three dimensions.

Next, the manufacturing process of the circuit substrate according to the present embodiment will be explained.

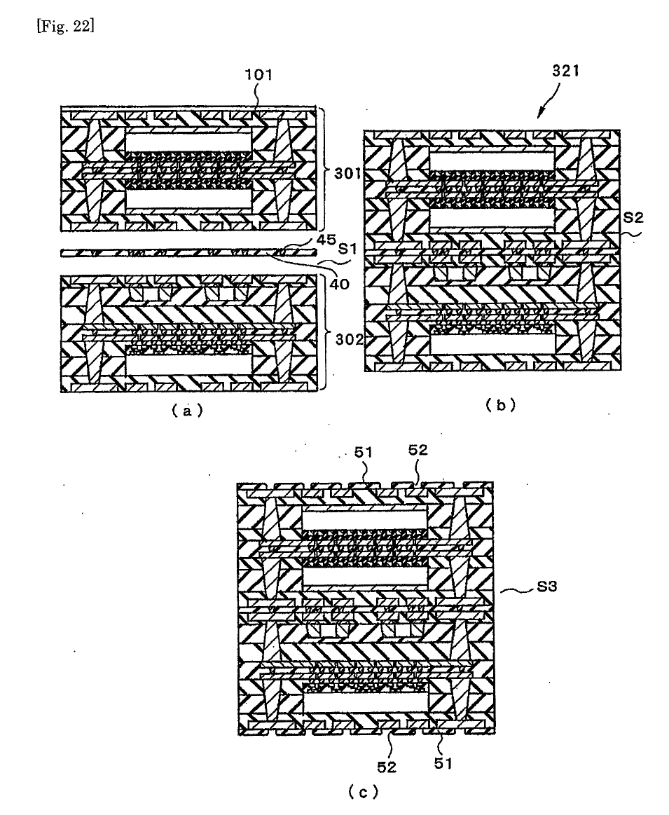

FIG. 22(a) and (b) are schematic views illustrating in stages the manufacturing process of the circuit substrate 321 according to the present embodiment. In FIG. 22, the notation of the same constitutional element with that in FIGS. 1 to 21 is identical, and then the detailed explanation of the element is omitted.

First, as shown in FIG. 22(a), in the arrangement of two the circuit substrates 301 and 302 with up and down, as the upper circuit substrate 301 there is used the same which was used in the step before the support plate 101 was removed. Also, between the lower circuit substrate 302 and the upper circuit substrate 301 there is disposed the adhesion layer 40 filled with solder paste or conductive paste, and with the conductive via 45 perforated between the front and rear faces (Step 1).

Then, in the state that the two circuit substrates 302 and 301 are arranged up and down through the adhesion layer 40 with the conductive via 45, the insulating connection due to the adhesion layer 40 and the conductive connection due to the conductive via 45 filled with solder paste or conductive paste are simultaneously performed, using the vacuum press method and so on.

By means of the insulating connection due to the adhesion layer 40 and the conductive connection due to the conductive via 45 formed with this adhesion layer 40 and filled with the conductive paste, the conductive wiring formed on the rear face of the circuit substrate 301 disposed in the upper portion and the conductive wiring formed on the front face of the circuit substrates 302 disposed in the lower portion are connected, thereby laminating the two circuit substrates 301 and 302 vertically. And thereafter, the support plate 101 is removed by the method of removing the support plate 101 stated above (Step 2). In the case, needless to say, the support plate 101 should be removed in advance from the faces of the sides of the circuit substrates 301 and 302 contacting the adhesion layer 40.

Also, it is possible to laminate one circuit substrate with the other circuit substrate by the vacuum press, through supplying the adhesion layer 40 on the surface of the one circuit substrate by the lamination processing or the press method, then forming the conductive via 45 using the methods stated above such as laminating the protective films on the surface of the adhesion layer 40. Though it is possible to perform in the atmosphere the resin supply, and the lamination processing and the pressing for connecting the circuit substrates therebetween, it is preferable to do so in vacuum because of enabling to remove the void remaining within resin.

Also, the circuit substrate 321 (FIG. 22(b)) formed as stated above can be used as it is. However, it is possible to use for multi device implementation by further forming solder resist having a given aperture (Step 3). Also, by means of making the circuit substrate 321 as a core substrate, it is possible to form further conductive wiring layers on both faces of the core substrate using the additive method, the semi additive method or the subtractive method.

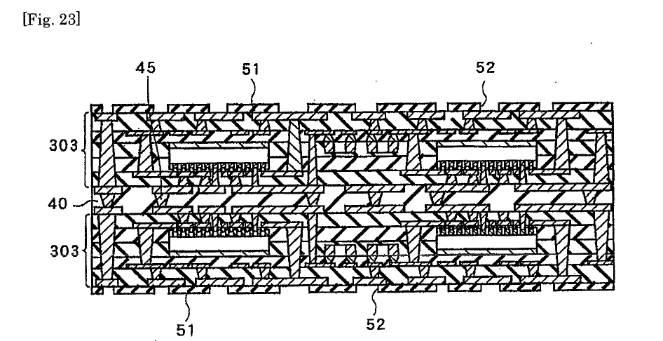

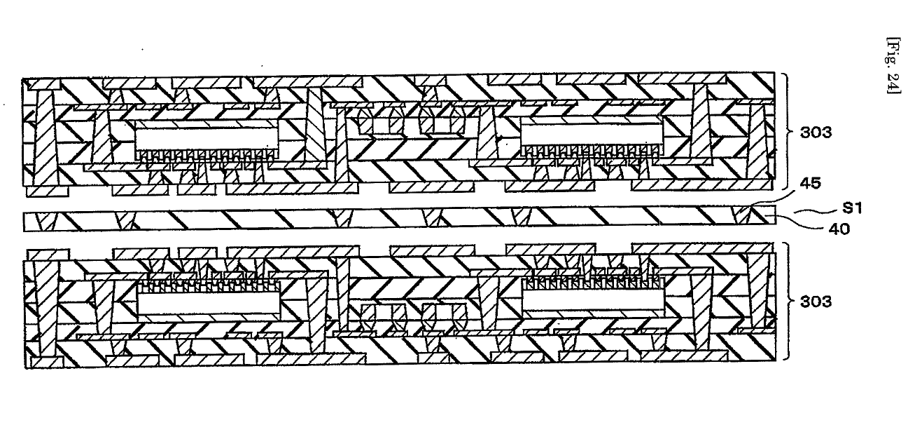

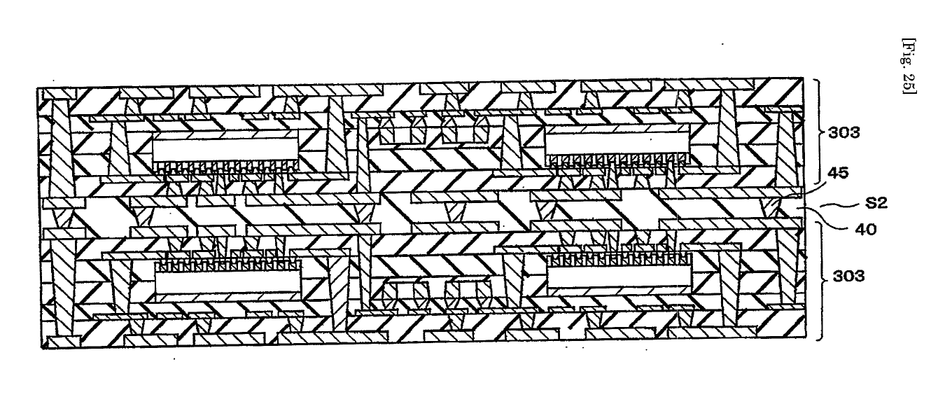

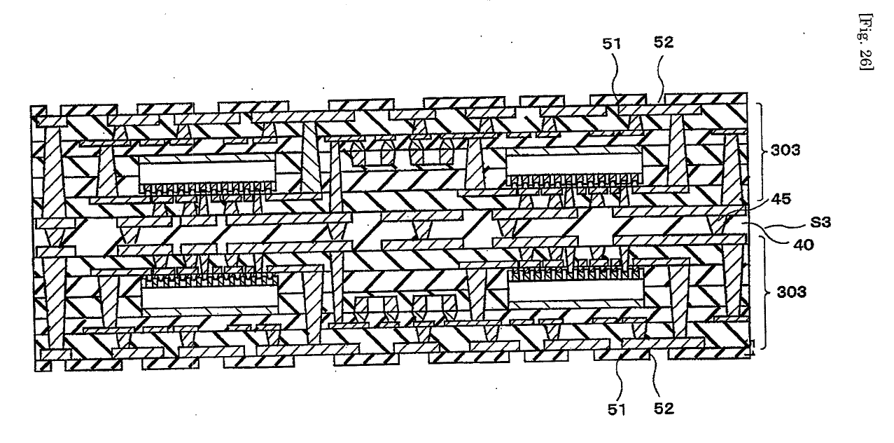

Next, the circuit substrate according to the sixteenth embodiment of the present invention will be explained. FIG. 23 is a schematic sectional view illustrating a circuit substrate according to the present embodiment. In FIG. 23, the notation of the same constitutional element with that in FIGS. 1 to 22 is identical, and then the detailed explanation of the element is omitted.

In the circuit substrate according to the present embodiment, like the circuit substrate according to the thirteenth embodiment stated above, there are arranged two circuit substrates 303 on which a plurality of function elements are mounted in the horizontal direction such that the electrode terminals contained within those function elements are disposed with face to face. Between the two circuit substrates 303 there is disposed the adhesion layer 40 made of insulator, with the conductive via 45 perforated between the front and rear faces.

By means of the insulating connection due to the adhesion layer 40 made of insulator and the conductive connection due to the conductive via 45 formed with this adhesion layer 40 and filled with the conductive paste, the conductive wiring of the circuit substrate 303 disposed in the upper portion and the conductive wiring of the circuit substrates 303 disposed in the lower portion are connected, thereby laminating the two circuit substrates 303 vertically.

And, there is provided with the solder resist 51 formed with the aperture 52 in the electrode terminal on the front and rear faces of the laminated circuit substrates. Thus, the circuit substrate according to the present embodiment is constituted.

Then, the performance of the circuit substrate according to the present embodiment, constituted as stated above will be explained.

In the present embodiment because the solder resist 51 is provided, it is possible to reduce the possibility in occurrence of electric short by solder melting between the conductive wirings when implementing the surface mounting, thereby obtaining the product with high reliability.

Next, the manufacturing process of the circuit substrate according to the present embodiment will be explained.

FIGS. 24 to 26 are schematic views illustrating in stages the manufacturing process of the circuit substrate according to the present embodiment.

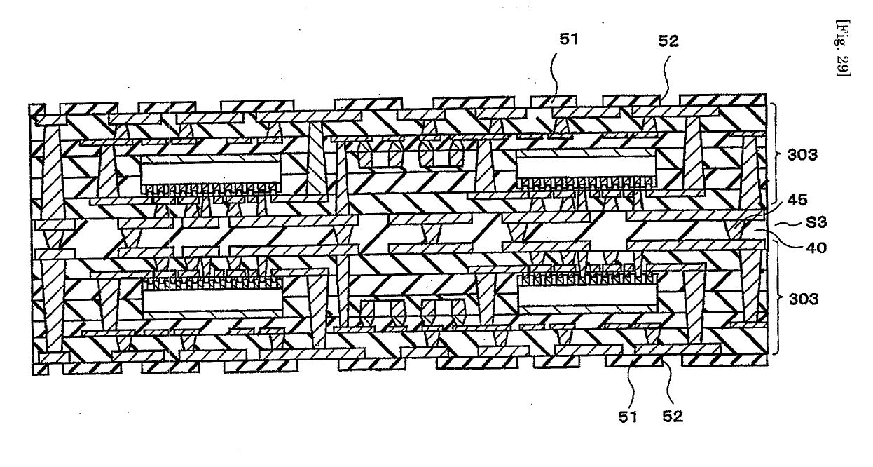

FIGS. 27 to 29 are schematic views illustrating in stages another manufacturing process of the circuit substrate according to the present embodiment.

FIGS. 30 to 32 are schematic views illustrating in stages still another manufacturing process of the circuit substrate according to the present embodiment.

In FIGS. 24 to 32, the notation of the same constitutional element with that in FIGS. 1 to 23 to 32 is identical, and then the detailed explanation of the element is omitted.

First, there is disposed the adhesion layer 40 with the conductive via 45 filled with solder paste or conductive paste and perforated through on the circuit substrate 303 according to the twelfth embodiment. Then, there is disposed the circuit substrate 303 according to the twelfth embodiment with upside down (FIG. 24, step 1).

In the state that the two circuit substrates 303 are arranged up and down through interleaving the adhesion layer 40 with the conductive via 45, the insulating connection due to the adhesion layer 40 and the conductive connection due to the conductive via 45 filled with solder paste or conductive paste are simultaneously performed, using the vacuum press method and so on.

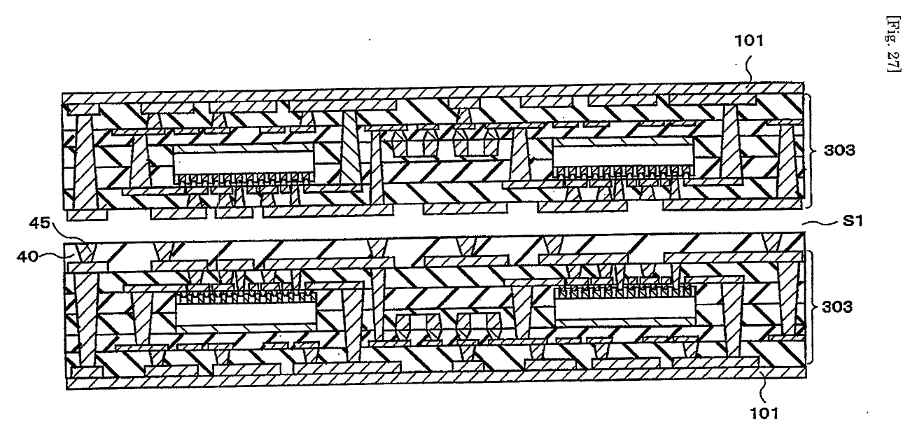

By means of the insulating connection due to the adhesion layer 40 and the conductive connection due to the conductive via 45 formed with this adhesion layer 40 and filled with the conductive paste, the conductive wiring 3b of the circuit substrate 303 disposed in the upper portion and the conductive wiring 3b of the circuit substrate 303 disposed in the lower portion are connected, thereby laminating the two circuit substrates vertically (FIG. 25 step 2).

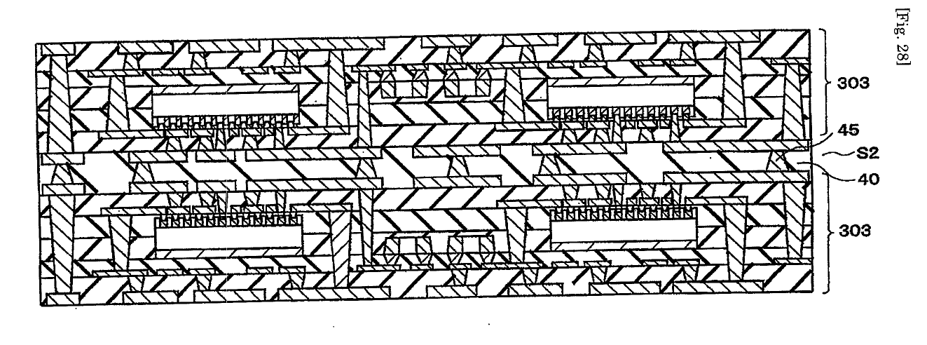

Thereafter, there is still formed the solder resist with given apertures on the front and rear faces of this laminated circuit substrate (FIG. 26 step 3).

Thus, the circuit substrate according to the present embodiment can be obtained.

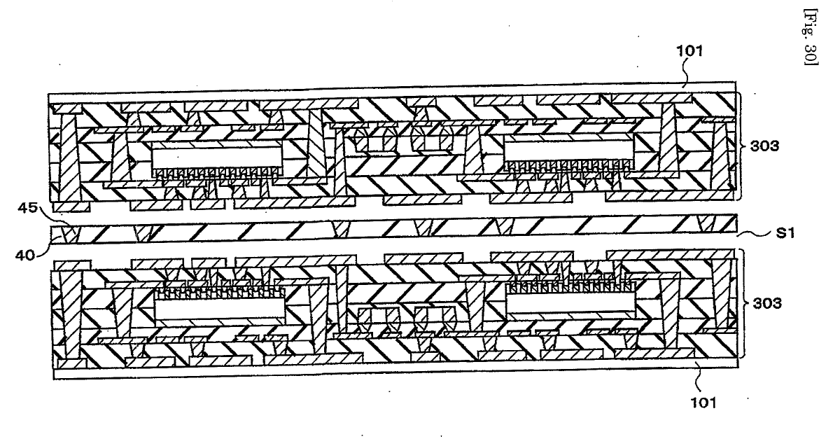

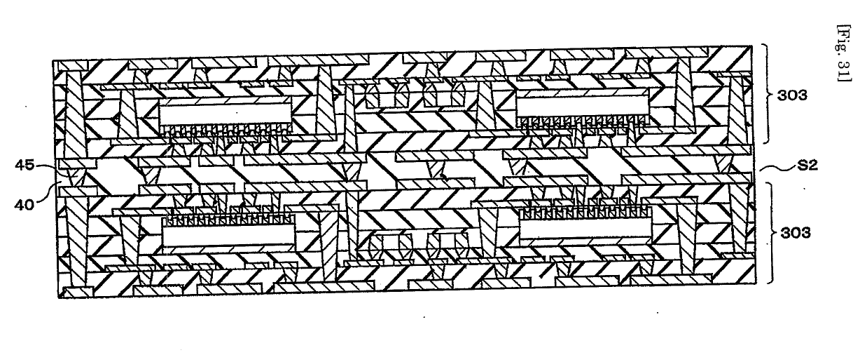

Also, as shown in FIGS. 27 to 29, there is formed the conductive via 45 by the steps of using two of the circuit substrate 303 in the step before removing the support plate 101, supplying in advance the adhesion layer 40 on the surface of one circuit substrate 303, forming the via hole using the laser beam and so on and filling solder paste or conductive paste inside the via hole (FIG. 27 step 1). Then, there is disposed the other circuit substrate 303 with the state upside down in respect to the state shown in FIG. 12. Then, there is laminated the two circuit substrates vertically in the similar step to the step 2 in FIG. 24. Then, there is removed the support plate 101 on the front and rear faces by the method for removing stated above (FIG. 28 step 2). Thereafter, there is still formed the solder resist with given apertures on the front and rear faces of this laminated circuit substrate (FIG. 29 step 3).

Thus, the circuit substrate according to the present embodiment can be obtained. Also, in the step 1 it is possible to use two of the circuit substrate 303 in which the support plate 101 was removed.

Also, as shown in FIGS. 30 to 32, it is possible to obtain the circuit substrate according to the present embodiment through the following steps of using the circuit substrate 303 in the step before removing the support plate 101, disposing the adhesion layer 40 with the conductive via 45 filled through with solder paste or conductive paste on one circuit substrate 303, disposing the other circuit substrate 303 thereon in the state upside down (FIG. 30 step 1),

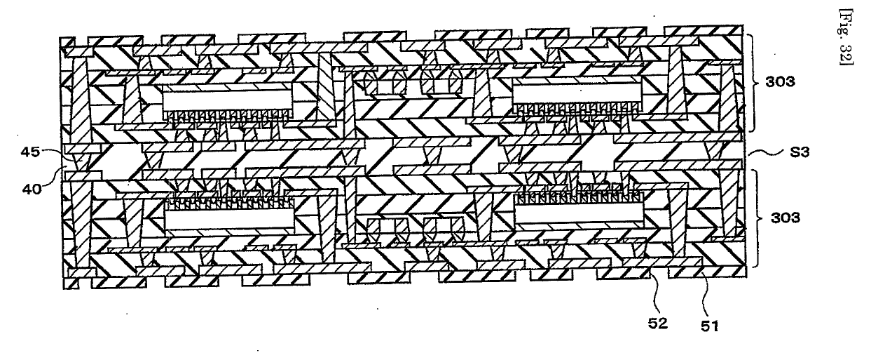

Then, laminating the two circuit substrates vertically in the similar step to the step 2 in FIG. 28, removing the support plate 101 on the front and rear faces by the method for removing stated above (FIG. 31 step 2), and thereafter, forming the solder resist with given apertures on the front and rear faces of this laminated circuit substrate (FIG. 32 step 3).

In the manufacturing process for the circuit substrate according to the present embodiment, it is possible to laminate even after the support plate 101 of the circuit substrate 303 is removed. However, in case that there is disposed the support plate 101 on at least one of the circuit substrates 303, it is possible to enhance reliability in connection between the circuit substrates 303 due to the adhesion layer 40 and the conductive via 45, because whole of the circuit substrates 303 are uniformly pressed when pressing in vacuum.

Also, in the present embodiment it is illustrated that the two circuit substrates containing the same function element 1 are laminated in the vertical direction. However, without such a limitation, it is possible to laminate the two circuit substrates containing different kind of function elements therein.

For example, in the circuit substrate according to the present embodiment, as the adhesion layer 40, it is possible to use the glass cloth-containing epoxy resin, usually called prepreg or aramide non woven sheet-containing epoxy resin and with the thickness of 20 to 80 μm.

Also, as the adhesion layer 40 in another way, it is possible to use such a thing made of semi hardened thermosetting resin or thermoplastic resin, which is provided with the conductive via 45 filled with solder paste or conductive paste including at least one kind of element among Sn, Ag, Cu, Bi, Zn and Pb, and with the thickness of 20 to 100 μm.

Further, as the adhesion layer 40 in another way, it is possible to use such a thing which is obtained, in the state that the protective films such as PET (Poly Ethylene Terephthalate) with the thickness of 25 to 38 μm or PEN (Poly Ethylene Naphthalate) and so on is laminated on both sides of the prepreg material and so on, by the steps of forming a through via hole by means of the laser beam processing in diameters of 30 μm to 500 μm or the drill in diameters of 80 μm to 500 μm, then filling solder paste or conductive paste inside the via hole through printing the solder paste or the conductive paste onto the protective films using the protective films instead of a mask, and then removing the protective films.

Also, in the case, it is possible to print using a metal mask made of stainless or nickel, or a screen mask, without use of the protective films.

In the step 1 of FIG. 27, as the method for supplying the adhesion layer 40 with the conductive via 45 on the surface of one circuit substrate 303, it is possible to use such a way of,

supplying resin through the lamination or press method on the surface of one circuit substrate 303, then forming the via hole by the laser beam and so on, forming the conductive via 45 using the method and so on for laminating the protective films on the surface of the adhesion layer 40, and then removing the protective films.

Though it is possible to perform in the atmosphere the resin supply, and the lamination processing and the pressing for connecting the circuit substrates therebetween, it is preferable to do so in vacuum because of enabling to remove the void remaining within resin.

Also, the solder resist can be formed in the thickness of 5 to 40 μm.

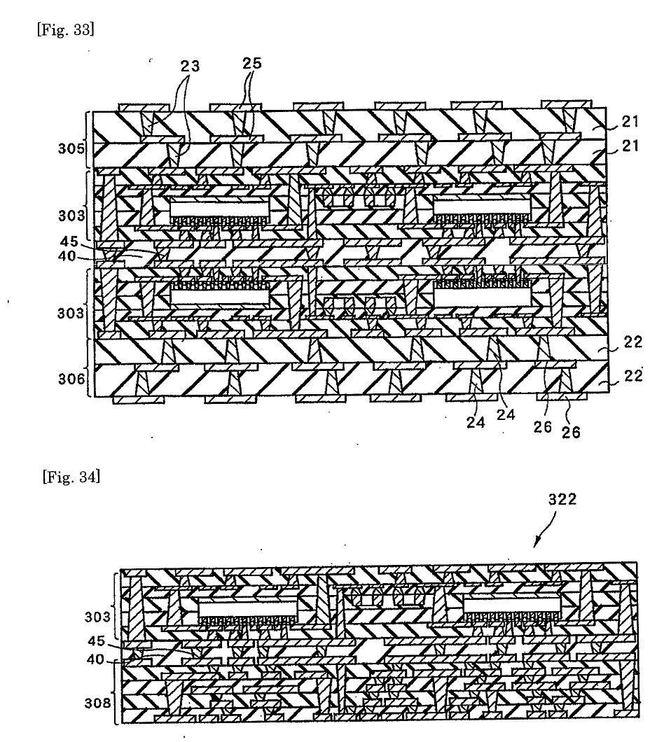

Next, the circuit substrate according to the seventeenth embodiment of the present invention will be explained. FIG. 33 is a schematic sectional view illustrating a circuit substrate according to the present embodiment. In FIG. 33, the notation of the same constitutional element with that in FIGS. 1 to 32 is identical, and then the detailed explanation of the element is omitted.

In the circuit substrate according to the present embodiment, such a circuit substrate (FIGS. 25, 28 and 31, step 2) is used as the core substrate, in which solder resist is not formed on the front and rear faces of the circuit substrate according to the sixteenth embodiment.

On both sides of this circuit substrate there is formed an insulating resin layer on which is provided with a conductive wiring layer obtained by forming a conductive wiring using the additive construction method, the semi additive construction method or the subtractive construction method.

Plural of this conductive wiring layer are laminated (There are illustrated a build up layer 305 consisting of two layers of the conductive wiring layer at the upper face, and a build up layer 306 consisting of two layers of the conductive wiring layer at the lower face.), and those conductive wiring layers are connected by the conductive via.

Then, the performance of the circuit substrate according to the present embodiment, constituted as stated above will be explained.

In the circuit substrate according to the present embodiment, it is possible to easily enlarge the arrangement of the electrode terminal of the recent miniaturized function element as it comes up to the surface of the circuit substrate. Also, in the circuit substrate according to the present embodiment, because the conductive wiring is formed by the additive construction method, the semi additive construction method or the subtractive construction method, it is possible to make use of the facility used in usual manufacturing process, and to manufacture with low cost without introducing new facilities.

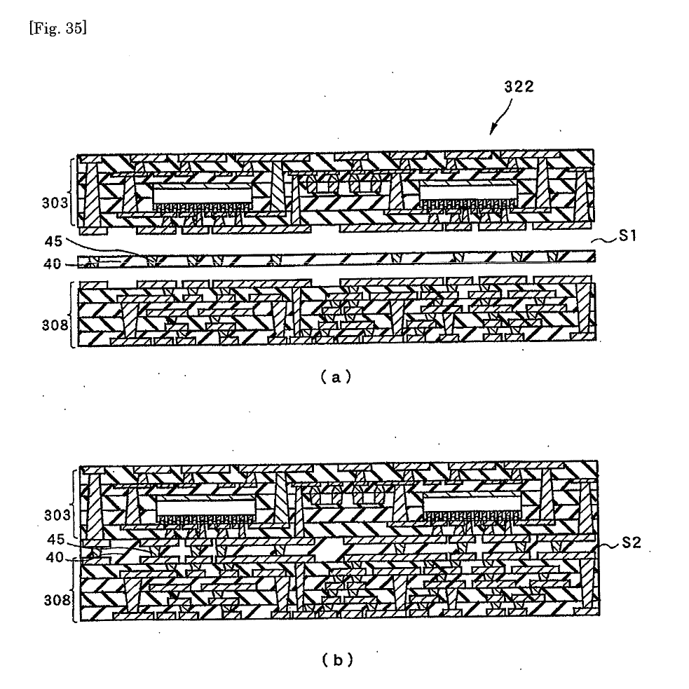

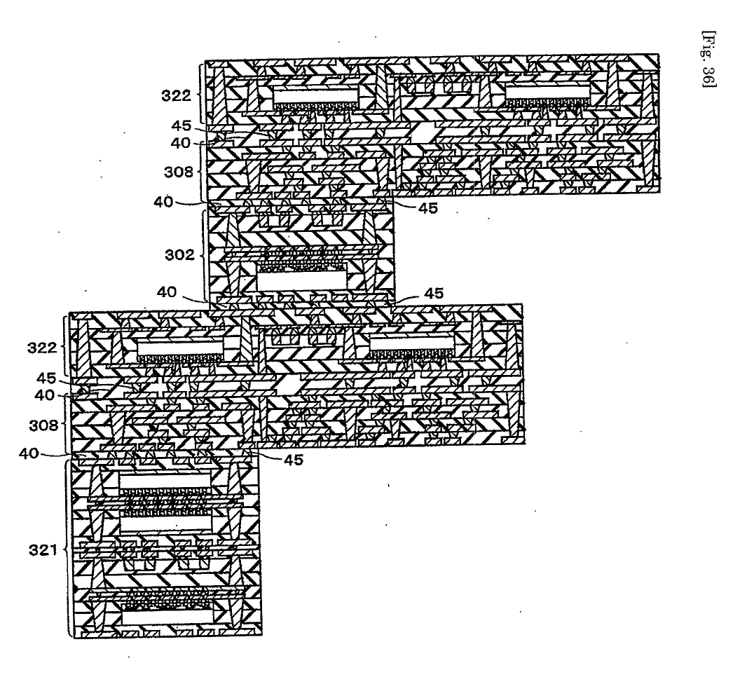

Next, the circuit substrate according to the eighteenth embodiment of the present invention will be explained. FIG. 34 is a schematic sectional view illustrating a circuit substrate according to the present embodiment. In FIG. 34, the notation of the same constitutional element with that in FIGS. 1 to 33 is identical, and then the detailed explanation of the element is omitted.

In the circuit substrate according to the present embodiment, the circuit substrate 303 according to the thirteenth embodiment stated above is arranged with the state upside down in respect to the state shown in FIG. 19. And, this circuit substrate 303 and a multilayered wiring substrate 308 are vertically laminated in a way that by means of the insulating connection due to the adhesion layer 40 made of insulator and the conductive connection due to the conductive via 45 formed through the front and rear faces of the adhesion layer 40, which is embedded with the conductive paste, the conductive wiring of the circuit substrate 303 disposed at the upper portion and the conductive wiring of the multilayered wiring substrate 308 disposed at the lower portion are connected. Thus, the circuit substrate 322 according to the present embodiment is constituted. Here, any of organic material and inorganic material can be used as the base member for the multilayered wiring substrate 308.

Then, the performance of the circuit substrate according to the present embodiment, constituted as stated above will be explained.

Through thus constituted, in the circuit substrate 322 according to the present embodiment, there is an advantage that it is possible to solve the problem of difficulty to realize the multi-layered substrate in the prior art of the circuit substrate containing the function element therein, and to improve high speed electric signal characteristics not only in the function element contained therein, but also in the electronic component implemented in the form of surface mounting.

Also, in the conventional semiconductor packaging, there is performed the flipchip connection or wire bonding connection to the small substrate called “Interposer” and then the outer circumference is sealed by resin. However, in case of implementing the semiconductor in the circuit substrate 322 according to the present embodiment, it is possible to simultaneously process the plural steps in which the semiconductor package is connected through the surface mounting to the circuit substrate when manufacturing the circuit substrate.

Accordingly, it is possible to reduce the cost extremely.

Next, the manufacturing process of the circuit substrate according to the present embodiment will be explained.

FIG. 35(a) and (b) are schematic views illustrating in stages the manufacturing process of the circuit substrate 322 according to the present invention. In FIG. 35, the notation of the same constitutional element with that in FIGS. 1 to 34 is identical, and then the detailed explanation of the element is omitted.

As shown in FIG. 35(a), the manufacturing process of the circuit substrate according to the present embodiment is constituted by the following steps of

first, disposing the multilayered wiring substrate 308 at the lower portion,

disposing the adhesion layer 40 with the conductive via 45 filled through with solder paste or conductive paste,

further disposing above thereon the circuit substrate 303 in the step before the support plate 101 is removed,

then connecting those by the press method and so on (Step 1),

removing the support plate 101 by the removing method stated above, and

obtaining the circuit substrate 322 according to the present embodiment (Step 2).

Also, in the case, when the multilayered wiring substrate 308 is provided with the support plate 101 made of metal or ceramics and so on in the face opposite to the face to which the multilayered wiring substrate 308 contacts the adhesion layer 40, it is possible to press uniformly when pressing, thereby enabling to form the circuit substrate with high reliability. It is preferable that the circuit substrate 303 is provided with the support plate 101 when the circuit substrate 303 is connected to the multilayered wiring substrate 308 through the adhesion layer 40 by the press method. However, it is also possible to connect the multilayered wiring substrate 308 through the adhesion layer 40 by the press method after the support plate 101 is removed.

The circuit substrate 322 formed as stated above has the excellent high speed electric characteristics, and it is possible to size down the circuit substrate.

Also, the circuit substrate 322 according to the present embodiment can be used as it is. However, it is possible to use for implementing multi-device by further forming solder resist with given aperture on the surface of the circuit substrate 322.

Also, by means of making the circuit substrate 322 as a core substrate, it is possible to form further conductive wiring layers on both faces of the core substrate using the additive method, the semi additive method or the subtractive method.

Next, the circuit substrate according to the nineteenth embodiment of the present invention will be explained. FIG. 36 is a schematic sectional view illustrating a circuit substrate according to the present embodiment. In FIG. 36, the notation of the same constitutional element with that in FIGS. 1 to 35 is identical, and then the detailed explanation of the element is omitted.

In the circuit substrate according to the present embodiment, as the four circuit substrates with the outer shape different, in sequence from below, the circuit substrate 321 according to the fifteenth embodiment stated above, the circuit substrate 322 according to the eighteenth embodiment stated above, the circuit substrate 302 stated above and the circuit substrate 322 stated above are laminated by means of the insulating connection due to the adhesion layer 40 made of insulator and the conductive connection due to the conductive via 45 formed through the front and rear faces of this adhesion layer 40 and filled with the conductive paste.

Then, the performance of the circuit substrate according to the present embodiment, constituted as stated above will be explained.

In the circuit substrate according to the present embodiment, even when dimensions of the outer shape in the circuit substrates to be laminated are different, it is possible to form the circuit substrate in the form of three dimensions by connecting and laminating between those circuit substrates through the insulating connection due to the adhesion layer 40 made of insulator and the conductive connection due to the conductive via 45 formed through the front and rear faces of this adhesion layer 40 and filled with the conductive paste. Thus, it is possible to increase the mounting area which was limited to small in respect to the surface mounting of the circuit substrate in the prior art, and also, it is possible to perform circuit design so as to effectively shorten the distance between the function elements, thereby effecting to form the product with high performance.

As explained above, according to the present invention,

since the conductive wiring formed on either one of the front side or the rear side of the circuit substrate containing the function element therein is arranged such that the surface of the conductive wiring exposed outside from the base member is in the same plane with or inside the surface of the base member on which the conductive wiring is formed, it is possible to directly implement the surface mounting and so on for electronic components on the surface of conductive wirings without forming solder resist.

Also, since it is possible to simultaneously perform the connection of the function element to the circuit substrate and the formation of the circuit substrate, the manufacturing cost can be reduced.

Also, it is possible to integrate two or more than two of the function element with short distances inside the circuit substrate in the form of three dimensions, thereby enabling to obtain high speed electric characteristics.

Also, in case that the function element is contained, which is lower in heat generation when operating, it is possible to provide with the wiring pattern for the heat dissipation in the circuit substrate in order to induce the heat dissipation of the function element. Also, since the wiring pattern can be freely designed such that the stress is relaxed which is generated between the conductive wiring of the circuit substrate and the function element due to the difference of thermal expansion coefficients, it is possible to obtain the circuit substrate with high reliability.

Also, since the outward shape of the circuit substrate containing the function element therein is larger than that of the function element to be contained, it is possible to expand the wiring rule for the electrode terminal of the function element at the front and the rear of the circuit substrate and to implement with excellent workability and reliability when the circuit substrate and a electronic device are connected in the following process.

Also, according to the manufacturing process for the circuit substrate according to the present invention, the conductive wiring layer is formed on the support plate, and then the function element is mounted on the conductive wiring layer. In the case, even when the function element is brittle, it is possible to reduce the stress applied to the function element due to addition of pressing force when mounting, thereby preventing the function element from deformation and broken.

Also, since the conductive wiring is exposed from the rear face of the circuit substrate by removing the support plate, the exposed face of the conductive wiring can be positioned in the same plane with the rear face of the insulating resin layer, or in the dimple on the inside, whereby the insulating resin layer can play the role of solder resist without supplying the solder resist, and the height of the conductive wiring becomes uniformly because the conductive wiring is formed on the support plate. Accordingly, it is possible to obtain high reliability in connection when implementing semiconductor and so on.

1. A circuit substrate comprising
a function element with an electrode terminal,
a base member containing said function element therein, said base member being provided with at least one layer of a conductive wiring formed on each front side face and rear side face thereof,
a via connecting said electrode terminal to said conductive wiring formed on said base member, wherein said conductive wiring formed on either one of the front side face or the rear side face of said base member is arranged such that the surface of the conductive wiring exposed outside from the base member is in the same plane with or inside the surface of the base member on which the conductive wiring is formed.

2. A circuit substrate comprising
a function element with an electrode terminal extending in the direction perpendicular to a surface of said function element,
a base member containing said function element therein and having at least one layer of a conductive wiring formed on its front side face and rear side face respectively, and
a via connecting said electrode terminal with said conductive wiring formed on the front side face of the base member, wherein the conductive wiring formed on the rear side face of the base member is arranged such that a surface exposed outside from the base member is in the same plane with or inside a surface of the base member on which the conductive wiring is formed.

3. The circuit substrate according to claim 1, said base member is formed with at least one layer made of resin layers.

4. The circuit substrate according to claim 1, wherein said base member is formed with three layers made of resin layers, and wherein an insulating layer contacting a side face of the function element of said base member has a thermal expansion coefficient smaller than those of other insulating layers.

5. The circuit substrate according to claim 4, wherein the thermal expansion coefficient of the resin layer contacting the side face of the function element is within +30% of the thermal expansion coefficient of the function element.

6. The circuit substrate according to claim 1, wherein there are provided with on the front side face and the rear side face of the base member, a plurality of wiring layers consisting of a insulating layer and a conductive wiring on the insulating layer, and at least one via connecting between the conductive wirings formed on different wiring layers.

7. The circuit substrate according to claim 6, wherein there is provided with at least one via connecting the conductive wiring of said wiring layer formed on the front side face of the base member to the conductive wiring of said wiring layer formed on the rear side face of the base member.

8. The circuit substrate according to claim 7, wherein said via connecting the conductive wiring of said wiring layer formed on the front side face of the base member to the conductive wiring of said wiring layer formed on the rear side face of the base member is formed on both side faces interleaving said function element.

9. The circuit substrate according to claim 6, wherein there exist two or more than two kinds of combinations among the wiring layers provided with such a via connecting between the conductive wirings of the wiring layers formed on the front and the rear side faces of the function element.

10. The circuit substrate according to claim 6, wherein two or more than two layers of the wiring layers are formed on the surface of said function element, and wherein the electrode terminal of the function element is connected through at least one via to conductive wirings of wiring layers other than the wiring layer formed immediately above.

11. The circuit substrate according to claim 6, wherein three or more than three layers of the wiring layers are totally formed on the front and the rear faces of said function element, and wherein conductive wirings of each wiring layer are connected through at least one via to conductive wirings of wiring layers other than the wiring layers disposed immediately above and below.

12. The circuit substrate according to claim 1, wherein a direction to which each inner diameter of said via in the vertical direction is enlarged, is all in the same direction.

13. The circuit substrate according to claim 1, wherein there is provided with at least one wiring layer on front and rear faces of a core substrate which is used for as the circuit substrate.

14. The circuit substrate according to claim 1, wherein said circuit substrate contains at least one kind and two or more than two of the function elements therein.

15. The circuit substrate according to claim 1, wherein said circuit substrate contains at least two or more than two of the function elements therein, between which are electrically connected through conductive wirings.

16. The circuit substrate according to claim 1, wherein all function element is disposed in the horizontal direction to said base member and connected.

17. The circuit substrate according to claim 1, wherein the electrode terminals of all function element are formed to extend in the direction vertical to the surface.

18. The circuit substrate according to claim 1, wherein a part or all of the function element are electronic components, and wherein said electronic components are connected to the conductive wirings by means of solder made of material including at least one kind of elements selected from a group consisting of Sn, Ag, Cu, Bi, Zn and Pb.

19. A circuit substrate, wherein a plurality of said circuit substrates according to claim 1, are vertically laminated, and wherein the function elements of at least two circuit substrates are electrically connected through the conductive wirings.

20. The circuit substrate according to claim 19, wherein at least two circuit substrates are arranged such that the electrode terminals of the function element are disposed in the form of face to face.

21. The circuit substrate according to claim 19, wherein there is provided with the via due to conductive paste or solder paste between at least one pair of function elements, the one being on the circuit substrate disposed at the upper portion and the other being on the circuit substrate disposed at the lower portion.

22. A circuit substrate, wherein said circuit substrate according to claim 21 is connected to a multi-layered wiring substrate which is formed by means of a plurality of insulating layers, the via and the conductive wiring, through said via due to conductive paste or unleaded solder made of material including at least one kind of elements selected from a group consisting of Sn, Ag, Cu, Bi, Zn and Pb and an adhesion layer.

23. The circuit substrate according to claim 1, wherein there is provided with solder resist having an aperture on the front side face and the rear side face of said circuit substrate.

24. A circuit substrate further containing said circuit substrate according to claim 1 therein.

25. An electronic device arrangement, wherein there is provided with the circuit substrate containing said circuit substrate according to claim 1 therein.

26. A manufacturing process for a circuit substrate comprising the steps of:
forming at least one layer of a conductive wiring on a support plate,
mounting a function element on the conductive wiring,
containing said function element therein by sealing outer circumference of the function element with a resin layer,
forming a via at a portion of electrode terminal of the function element,
forming at least one layer of wiring layers on the function element and
removing said support plate.

27. A manufacturing process for a circuit substrate comprising the steps of:
forming at least one layer of a conductive wiring on a support plate,
forming at least one layer of resin layers on the conductive wiring,
mounting a function element on the conductive wiring,
containing said function element therein by sealing outer circumference of the function element with the resin layer,
forming a via at a portion of electrode terminal of the function element,
forming at least one layer of wiring layers on the function element and
removing said support plate.

28. The manufacturing process for the circuit substrate according to claim 24, wherein two or more than two kinds of said function elements are mounted.

29. The manufacturing process for the circuit substrate according to claim 26, wherein a part or all of said function element are electronic components, and wherein said mounting is so constituted that said electronic components are connected to the conductive wirings by means of solder made of material including at least one kind of elements selected from a group consisting of Sn, Ag, Cu, Bi, Zn and Pb.

30. The manufacturing process for the circuit substrate according to claim 26, wherein said manufacturing process for the circuit substrate further includes the steps of:
forming a via hole in the insulating resin from the opposite side to said supporting plate and
implementing metallic plating inside said via hole.

31. A manufacturing process for a circuit substrate, wherein as a core substrate, using the circuit substrate manufactured by the manufacturing process for the circuit substrate according to claim 26, and wherein said process further includes the step of:
building up a wiring layer on a front face and a rear face of the core substrate.

32. A manufacturing process for a circuit substrate, wherein said process includes the steps of:
disposing two pieces of the circuit substrate, which are manufactured by the manufacturing process for the circuit substrate according to claim 26, with face to face in up and down and
connecting by interleaving an adhesion layer provided with the via filled with conductive paste or solder paste between said two pieces of the circuit substrates.

33. A manufacturing process for a circuit substrate, wherein said process includes the steps of:
forming at least one layer of a conductive wiring on a support plate,
disposing two pieces of the circuit substrate, which are manufactured by the manufacturing process for the circuit substrate according to claim 26, with face to face in up and down and
connecting by interleaving an adhesion layer provided with the via filled with conductive paste or solder paste between said two pieces of the circuit substrates.

34. The manufacturing process for the circuit substrate according to claim 33, wherein said process includes the step of:
removing the support plate by means of using at least one before removal among the two pieces of circuit substrates.

35. A manufacturing process for a circuit substrate, wherein said process includes the steps of:
disposing the circuit substrate manufactured by the manufacturing process for the circuit substrate according to claim 32 and other circuit substrate with face to face in up and down, and
connecting by interleaving an adhesion layer provided with the via filled with conductive paste or unleaded solder paste between said two circuit substrates, and wherein said disposing and connecting is performed at least one time.

36. The manufacturing process for the circuit substrate according to claim 35, wherein said process includes the step of:
removing the support plate by means of using at least one before removal among the two circuit substrates.

37. The manufacturing process for the circuit substrate according to claim 32, wherein said conductive paste or unleaded solder paste is made of material including at least one kind of element selected from a group consisting of Sn, Ag, Cu, Bi, Zn and Pb.

38. The manufacturing process for the circuit substrate according to claim 26, wherein said support plate is made of material which includes at least one kind of element selected from the group consisting of copper, iron, nickel, chromium, aluminum, titanium, silicon, nitrogen and oxygen.

39. A manufacturing process for a circuit substrate, wherein said process includes the step of:
forming solder resist with an aperture on at least one of the front and rear faces of the circuit substrate manufactured by the manufacturing process for the circuit substrate according to claim 26.
